(19) United States
(12) Patent Application Publication
(10) Pub. No.: US 2008/0237621 A1
(43) Pub. Date: Oct. 2, 2008

(54) LIGHT EMITTING DEVICE AND METHOD OF PRODUCING THE SAME

(75) Inventor: Masashi TAKEMOTO, Hiroshima (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 12/058,212

(22) Filed: Mar. 28, 2008

(30) Foreign Application Priority Data
Mar. 30, 2007 (JP) 2007-094991
Mar. 25, 2008 (JP) 2008-077425

(51) Int. Cl. H01L 33/00

(52) U.S. Cl. 257/98; 438/27; 257/E33.059; 257/E33.072

(57) ABSTRACT

To provide a light emitting device that is improved in intensity of light emitted from a light outgoing surface and has excellent heat releasing property, the light emitting device according to the present invention includes an LED chip 501 mounted on a substrate and an insulating section 509 formed on a front surface of the substrate and made of light-transmitting resin. The insulating section 509 has a multilayer structure constituted of a titanium dioxide-added resin layer 509c to which titanium dioxide is added and a titanium dioxide-free resin layer 509b to which no titanium dioxide is added.

This Nonprovisional application claims priority under 35 U.S.C. § 119(a) on Patent Application No. 094991/2007 filed in Japan on Mar. 30, 2007, and Patent Application No. 077425/2008 filed in Japan on Mar. 25, 2008, the entire contents of which are hereby incorporated by reference.

### FIELD OF THE INVENTION

The present invention relates to a light emitting device that is suitable for applying light to a thin display, such as a liquid crystal panel, from a side of the display, and relates to a method of producing the light emitting device.

### BACKGROUND OF THE INVENTION

Conventionally, as a backlight for laterally illuminating a display panel of liquid crystal or the like, a light emitting device such as a laterally light emitting diode (this diode will be referred to as “LED” hereinafter) mentioned in Japanese Unexamined Patent Publication No. 223082/2005 (Tokukai 2005-223082) (Publication date: Aug. 18, 2005) (this publication will be referred to as “Publication 1” hereinafter) or a similar document is used.

As illustrated in FIG. 42, a light emitting device 101 includes: a chip substrate 114 having a die-bond pattern 108 and an electrode terminal 109; an LED chip 103 provided on the chip substrate 114; a wire 116 for connecting the LED chip 103 to the electrode terminal 109; a reflecting frame 123 provided on the chip substrate 114 so as to surround the LED chip 103 and having an opening in an upper surface and in a part of a sidewall thereof; a reflecting surface 122 which is an internal periphery of the sidewall of the reflecting frame 123; a light-transmitting resin 119 provided on the chip substrate 114 so as to fill the reflecting frame 123 and having an opening that is formed in the sidewall and serves as a light projecting surface 117; and a reflecting film 121 covering an upper surface of the light-transmitting resin 119. The light emitting device 101 is arranged so that: light emitted from the LED chip 103 is reflected by a reflecting surface 122 of the reflecting frame 123 and by a reflecting film 121, and the reflected light is projected outward from the light projecting surface 117 formed on one side face.

Further, if heat generated in the light emitting device is not sufficiently radiated, the heat damages members of the element, so that light emission efficiency drops or the element per se is damaged. As a result, it is impossible to keep the long-term reliability. Thus, it is desired to develop a light emitting device having excellent heat radiating property.

For example, Japanese Unexamined Patent Publication No. 282004/2004 (Tokukai 2004-282004) (Publication date: Oct. 7, 2004) (the publication will be referred to as “Publication 2” hereinafter) discloses a light emitting device substrate having excellent heat radiating property.

With reference to FIGS. 15 and 16, an arrangement of the light emitting device substrate of Publication 2 is described as follows.

FIG. 15 is a cross sectional view illustrating an arrangement of a conventional light emitting device 1000 having the light emitting device substrate.

FIG. 16 is a diagram illustrating shapes of a conduction pattern 1008 and a wiring layer 1009 of the light emitting device substrate illustrated in FIG. 15.

As illustrated in FIG. 15, the light emitting device substrate has a first electrode 1004 and a second electrode 1005 as a conduction pattern 1003, and one electrode of an LED chip (not illustrated) is connected to the first electrode 1004, and the other electrode of the LED is connected to the second electrode 1005.

Further, the first electrode 1004, an interlayer connection pattern 1006, a protective metallic layer 1007, and a conduction pattern 1008 are sequentially formed between a lower side of a reflector 1001 and a lower side of a portion where the LED chip is formed. Note that, the conduction pattern 1008 is formed on the wiring layer 1009.

Further, a metallic laminate on and above which the first electrode 1004, the interlayer connection pattern 1006, the protective metallic layer 1007, and the conduction pattern 1008 are laminated is arranged so as to have a larger heat transmission area which allows transmission of heat of the reflector 1001. That is, as illustrated in FIG. 16, the conduction pattern 1008 occupies a large area.

As a result, the heat of the reflector 1008 can be efficiently transmitted via the protective metallic layer 1002 and the metallic laminate to a protective metallic layer 1012 and a metallic substrate 1010 which is a lowest layer.

Further, Japanese Unexamined Patent Publication No. 235778/2005 (Tokukai 2005-235778) (Publication date: Sep. 2, 2005) (the publication will be referred to as “Publication 3” hereinafter) discloses a structure that improves optical reflectance of surface resin. Specifically, inorganic filler is added to the surface resin of a multi-wiring substrate on which an LED chip is mounted, whereby the surface resin turns into white.

Generally, intensity of light emitted from the LED chip 103 is maximum in an upward direction indicated by an arrow 118 of FIG. 42. However, in the arrangement of Publication 1, the reflecting film 121 is formed in a light projecting direction of the LED chip 103 so as to be opposite to a light projecting surface of the LED chip 103. Thus, light emitted from the LED chip 103 is repetitively reflected between the reflecting film 121 and the chip substrate 114, so that a large part of the light emitted from the LED chip 103 is not efficiently projected outward from the light projecting surface 117. As a result, the light is absorbed by the reflecting film 121 and the chip substrate 114.

Further, according to the arrangement of the light emitting device 101 of Publication 1, a position of the light projecting surface 117 deviates by 90° from the upward direction (arrow 118) in which the intensity of the light emitted from the LED chip 103 is maximum. Thus, the light emitted from the LED chip 103 cannot be efficiently guided to the light projecting surface of the light emitting device 101 and cannot be projected outward from the element. Further, light which cannot be converted into fluorescent light or light which cannot be scattered in case of using fluorescent particles in a resin constituting the light-transmitting resin 119 is repetitively reflected between the reflecting film 121 and the chip substrate 114, so that a large part of the light is absorbed by the reflecting film 121 and the chip substrate 114. Further, variation in an amount of the fluorescent particles changes scattering degree, so that the light cannot be stably projected outward.

Recently, with thickness reduction of electronic devices such as mobile phones each having a liquid crystal panel, the laterally illuminating LED used for a liquid crystal backlight is required to be thinner. However, in a conventional structure described in Publication 1, as a distance between an upper surface of the LED chip 103 and the reflecting film 121 is shorter, the light absorption/light leakage results in greater loss. Hence, this raises such a problem that light is much less efficiently projected outward from the light emitting device.

Thus, it is desired to develop a laterally illuminating LED which can realize smaller thickness without decreasing efficiency at which light is projected outward.

Further, as illustrated in FIGS. 15 and 16, a light emitting device of Publication 2 is not arranged in such a manner that a metallic reflector 1001 surrounds an entire side face of the element in case where an installation surface on which the LED chip is formed is regarded as a bottom surface. Thus, light irradiated from the LED chip leaks outward from a part of the side face which part is not covered by the metallic reflector 1001.

Further, an insulating layer 1011 is formed on the installation surface except for an area where the first electrode 1004 is formed and an area where the second electrode 1005 is formed. Thus, out of light emitted from the LED chip, a large part of light moving toward the substrate passes through the resin insulating layer 1011 and leaks outward from a rear surface of the element.

The light which leaks in the foregoing manner is absorbed by other members provided on the outside of the element. This results in great energy loss in all. Thus, light emitted from the LED chip cannot be efficiently projected outward, so that intensity of light projected from the light projecting surface decreases.

Further, with the arrangement of Publication 3, the addition of the inorganic filler promotes oxidation of surrounding components owing to photocatalysis and/or causes an adverse effect due to hygroscopicity of the inorganic filler. Moreover, Publication 3 does not discuss a limitation on the amount of inorganic filler to be added.

### SUMMARY OF THE INVENTION

The present invention is in view of the foregoing problems, and has as an object to provide a light emitting device, and a method of producing the light emitting device, that is reduced in light leakage and improved in intensity of light emitted from a light outgoing surface and in heat releasing property to have excellent long-term reliability.

To solve the above problems, a light emitting device according to the present invention is adapted so that the light emitting device includes: an LED chip mounted on a substrate; and an insulating section formed on a front surface of the substrate and made of light-transmitting resin. The insulating section includes a light reflective filler-added area to which a light reflective filler is added and a light reflective filler-free area to which no light reflective filler is added.

With this structure, light that is emitted from the LED chip and enters the insulating section is reflected by the light reflective filler-added area. This makes it possible to reduce light that is partially absorbed and becomes attenuated when entering the insulating section and being reflected by a peripheral component, so that efficiency for light utilization and heat releasing property improve.

To solve the above problems, a light emitting device according to the present invention is adapted so that the light emitting device includes: a first metal section formed on a mount surface of a substrate and serving as a mount-surface metallic reflecting film; at least one second metal section that is formed on the mount surface and is electrically isolated from the first metal section by an insulating section; an LED chip mounted on the first metal section and having a first electrode that is electrically connected to the first metal section and a second electrode that is electrically connected to the second metal section; a metallic reflecting plate that is combined with the first metal section so as to surround the mount surface and reflects light emitted from the LED chip to guide the light to a light outgoing surface provided in a direction in which the light is emitted; and a light-transmitting sealant that fills an area surrounded by the substrate and the metallic reflecting plate and is formed in such a manner that the LED chip is sealed with the light-transmitting sealant. The insulating section is made of resin that contains a light reflective filler and being formed so as to surround the second metal section in an area surrounded by the metallic reflecting plate.

With this structure, the metallic reflecting plate that reflects light emitted from the LED chip and guides the light to the light outgoing surface provided in the direction in which the light is emitted is provided, in the direction in which the LED chip emits light, in such a manner as to surround the LED chip entirely. This allows the metallic reflecting plate to reflect light emitted from the LED chip to its surroundings and guides the light to the light outgoing surface efficiently. Thus, light leaking from a side surface of the element is reduced so that the intensity of light emitted from the light outgoing surface improves. Further, the inner side surface of the metallic reflecting plate closely adheres to the light-transmitting sealant. This makes it possible to prevent a problem that the metal peels off the inner side surface of the metallic reflecting plate. Thus, the inner side surface of the metallic reflecting plate is protected stably with the light-transmitting sealant.

Further, the first metal layer functions as a mount-surface metallic reflecting film and is formed so as to surround an outer edge of the second metal layer via the insulating section formed around an outer edge of the second metal layer. This makes it possible to form the first metal layer, which serves as the mount-surface metallic reflecting film, all over an area outside of a part of the mount surface of the substrate, which part includes the insulating section, while the first metal layer is kept isolated from the second metal layer. The first metal layer serving as the mount-surface metallic reflecting film is formed over a wide area of the mount surface. This allows much of light emitted from the LED and traveling toward the substrate to be guided to the light outgoing surface efficiently by the first metal section. Thus, it becomes possible to further reduce the amount of light absorbed by the substrate, so that the intensity of light emitted from the light outgoing surface improves.

Further, the insulating section is made of resin containing the light reflective filler. This allows light emitted from the LED chip and entering the insulating section to be reflected by the light reflective filler. Thus, it becomes possible to reduce light that is partially absorbed and becomes attenuated when entering the insulating section and being reflected by a peripheral component, so that the intensity of light emitted from the light outgoing surface improves.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is an oblique perspective view of a light emitting device of First Embodiment.

FIG. 2 is a sectional view of the light emitting device of First Embodiment.

FIGS. 3(a) to 3(h) each illustrate how a metallic reflecting plate and a multilayer substrate of the light emitting device of First Embodiment are arranged.

FIG. 4 is an oblique perspective view of the light emitting device of First Embodiment.

FIG. 5 an oblique perspective view of the light emitting device of First Embodiment.

FIG. 6 is an oblique perspective view of a light emitting device of Second Embodiment.

FIG. 7 is a sectional view of the light emitting device of Second Embodiment.

FIGS. 8(a) to 8(f) each illustrate how a metallic reflecting plate and a multilayer substrate of the light emitting device of Second Embodiment are arranged.

FIG. 9 is an oblique perspective view of the light emitting device of Second Embodiment.

FIG. 10 is an oblique perspective view of the light emitting device of Second Embodiment.

FIG. 11 is an oblique perspective view of the light emitting device of Second Embodiment.

FIG. 12 is a sectional view of the light emitting device of Second Embodiment.

FIG. 13 is an oblique perspective view of the light emitting device of Second Embodiment.

FIG. 14 is a sectional view of the light emitting device of Second Embodiment.

FIG. 15 is a sectional view of a conventional light emitting device.

FIG. 16 is a cross sectional view, taken along I-I, which illustrates the light emitting device illustrated in FIG. 26.

FIG. 17 is a sectional view of a light emitting device of Third Embodiment.

FIG. 18 schematically illustrates a state in which the light emitting device of Third Embodiment is provided in a housing of an electronic device.

FIG. 19 is a sectional view of a light emitting device of Fourth Embodiment.

FIG. 20 illustrates a schematic structure of the light emitting device of Fourth Embodiment.

FIG. 21 illustrates a schematic structure of a light emitting device of Fifth Embodiment.

FIGS. 22(a) to 22(h) each illustrate how a metallic reflecting plate and a multilayer substrate of the light emitting device of Fifth Embodiment are arranged.

FIG. 23 illustrates a schematic structure of the light emitting device of Second Embodiment.

FIG. 24 illustrates a schematic structure of the light emitting device of Second Embodiment.

FIG. 25 illustrates a schematic structure of the light emitting device of Second Embodiment.

FIG. 26 illustrates a schematic structure of the light emitting device of Second Embodiment.

FIG. 27 illustrates a schematic structure of the light emitting device of Third Embodiment.

FIG. 28 illustrates a schematic structure of the light emitting device of Third Embodiment.

FIG. 29 illustrates an example of electric potentials in the light emitting device of Third and Fourth Embodiments.

FIG. 30 illustrates an example of electric potentials in the light emitting device of Third Embodiment.

FIG. 31 illustrates an example of electric potentials in the light emitting device of Third Embodiment.

FIG. 32 illustrates a schematic structure of the light emitting device of Fourth Embodiment.

FIG. 33 illustrates a schematic structure of the light emitting device of Fourth Embodiment.

FIG. 34 illustrates a schematic structure of the light emitting device of Fourth Embodiment.

FIG. 35 illustrates a schematic structure of the light emitting device of Fifth Embodiment.

FIG. 36 illustrates an example of electric potentials in the light emitting device of Fifth Embodiment.

FIG. 37 illustrates an example of electric potentials in the light emitting device of Fifth Embodiment.

FIGS. 38(a) to 38(c) each illustrate how an insulating section of the light emitting device of First Embodiment is formed.

FIG. 39 illustrates how an insulating section of the light emitting device of First Embodiment is formed.

FIG. 40 illustrates a cross section of the light emitting device of First Embodiment after polishing is performed.

FIG. 41 illustrates a partially-enlarged cross section of the light emitting device shown in FIG. 40.

FIG. 42 is an oblique perspective view of a conventional laterally illuminating LED.

FIG. 43 is a sectional view of the light emitting device of Sixth Embodiment.

FIG. 44 is a graph showing a relationship between visible-light reflectance of the insulating section and the amount of light reflective filler added.

### DESCRIPTION OF THE EMBODIMENTS

### First Embodiment

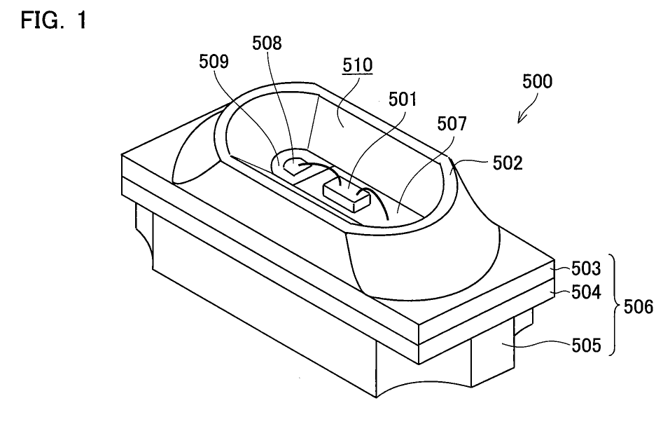

The following describes an embodiment of the present invention, with reference to FIGS. 1-5 and 38-41.

FIG. 1 is an oblique perspective view showing an exemplary structure of a light emitting device 500 of the present embodiment.

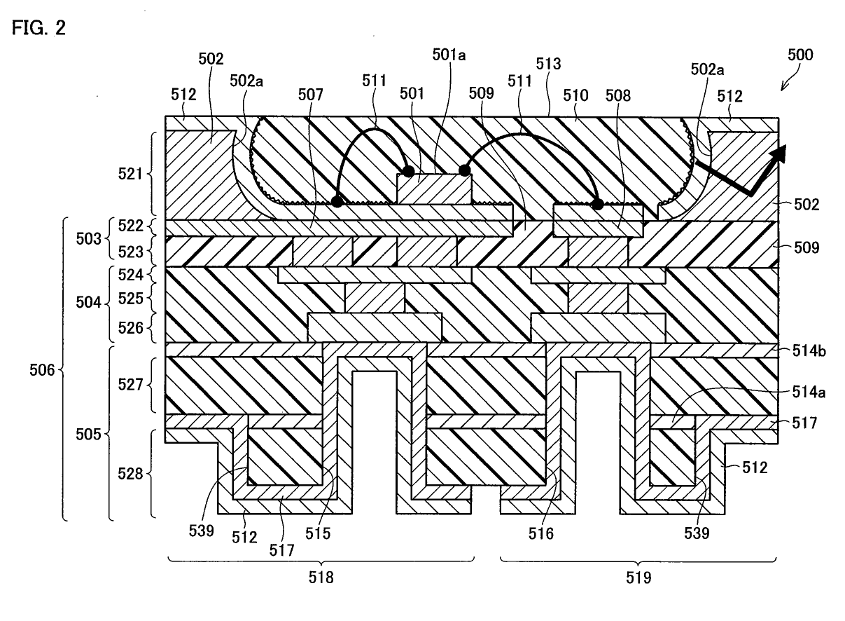

FIG. 2 is a sectional view showing a detailed structure of the light emitting device 500.

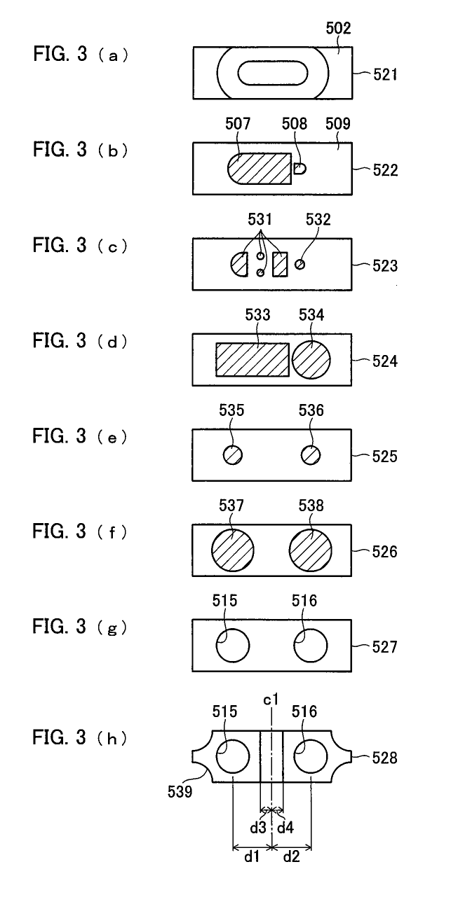

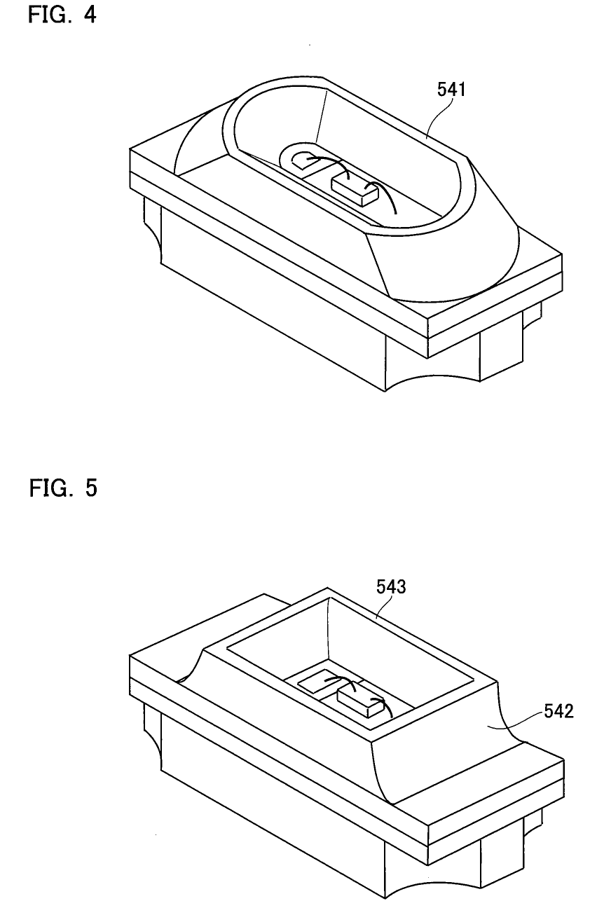

FIG. 3 shows a pattern of etching a metallic reflecting plate 502 and respective layers that constitute a multilayer substrate 506. FIG. 3(a) shows a first layer 521. FIG. 3(b) shows a second layer 522. FIG. 3(c) shows a third layer 523. FIG. 3(d) shows a fourth layer 524. FIG. 3(e) shows a fifth layer 525. FIG. 3(f) shows a sixth layer 526. FIG. 3(g) shows a seventh layer 527. FIG. 3(h) shows an eighth layer 528.

As shown in FIG. 1, the light emitting device 500 of the present embodiment includes an LED chip 501, which is mounted on the multilayer substrate 506, and the metallic reflecting plate 502. The metallic reflecting plate 502 stands along a direction in which the LED chip 501 emits light. The metallic reflecting plate 502 is provided on a mount surface in such a way as to surround an outer edge of the LED chip 501 completely. The metallic reflecting plate 502 reflects light emitted from the LED chip 501 to guide the light toward a light outgoing surface provided in the direction in which the LED chip 501 emits light. A light-transmitting sealant 510 is formed so as to fill in a part of the mount surface, which part is surrounded by the metallic reflecting plate 502.

The light emitting device 500 is configured in such a manner that a light emitting side faces, when mounted, a side surface of a liquid crystal panel installed on a display screen of a mobile phone or the like. In other words, the light emitting device 500 is configured to be used as a backlight that applies light to a liquid crystal panel from a side surface of the liquid crystal panel.

The LED chip 501 is a semiconductor chip made of GaN semiconductor material and the like, and emits blue light from a light emitting surface 501a. The LED chip 501 is mounted on a die-bonding-area/electrode section (first electrode section, mount-surface metallic reflecting film) 507 by die bonding in such a manner that the light emitting surface 501a comes an upper side. The light emitting surface 501a of the LED chip 501 includes an electrode terminal (not illustrated) constituted of an anode electrode and a cathode electrode.

The multilayer substrate 506 has a multilayer structure including a front layer 503, a middle layer 504, and a rear layer 505, which are formed one above the other in this order as listed, from a side close to the mount surface. As shown in FIG. 2, the multilayer substrate 506 has the multilayer structure constituted of the front layer 503, which has a dual-layer structure, the middle layer 504, which has a triple-layer structure, and the rear layer 505, which has a dual-layer structure. The multilayer substrate 506 having the foregoing structure is stacked on the metallic reflecting plate 502 to be combined with the metallic reflecting plate 502.

The following describes a detailed structure of the multilayer substrate 506, with reference to FIGS. 2 and 3.

First, the structure of the front layer 503 is described.

The front layer 503 has a dual-layer multilayer structure including the second layer 522 and the third layer 523 which are stacked in this order from a mount surface.

The mount surface is a surface of the second layer 522, i.e. a surface of the multilayer substrate 506, on which surface the LED chip 501 is to be mounted.

The die-bonding-area/electrode section (first metal section) 507 and an island electrode (second metal section) 508, each of which is connected to the LED chip 501, are formed on the second layer 522 (mount surface) to serve as electrode terminals that supply driving current to the LED chip 501. To electrically isolate the island electrode 508 from the die-bonding-area/electrode section 507, an insulating section 509 is formed so as to surround an outer edge of the island electrode 508.

The die-bonding-area/electrode section 507 is connected to the cathode electrode of the LED chip 501 by wire bonding (wire 511). The die-bonding-area/electrode section 507 and the metallic reflecting plate 502 are both made of a same kind of metal (copper in the present embodiment) and are combined.

It should be noted that materials of the die-bonding-area/electrode section 507 and materials of the metallic reflecting plate 502 are not limited to copper, and any other metal is usable. It is, however, preferable to use copper, silver, gold, or nickel, all of which are excellent in reflectance.

With the present embodiment, it is possible to form the metallic reflecting plate 502 so as to be combined with the die-bonding-area/electrode section 507, which serves as a mount-surface metallic reflecting film, by plating or the like without use of a bonding agent. Thus, unlike the conventional cases, heat generated when the LED chip 501 emits light does not stay in resin or the like that is low in heat conductivity. Instead, the heat is passed to the die-bonding-area/electrode section 507, which is formed on the substrate so as to be combined with the metallic reflecting plate 502, and released efficiently to a rear surface of the substrate. The metallic reflecting plate 502 and the die-bonding-area/electrode section 507 are combined so that the proportion of the metal to the entire element increases, whereby not only heat releasing property improves but also light leakage is prevented better.

To prevent damages due to a burr occurred at the time of dicing the light emitting device 500, the die-bonding-area/electrode section 507 is formed so as to leave a margin for dicing. This will be described in detailed later.

On the other hand, the island electrode 508, which is the other one of the electrode terminals, is made of copper and connected to the anode electrode of the LED chip 501 by wire bonding (wire 511). The island electrode 508 is provided on an island having an outer edge surrounded by the insulating section 509, within a part of the second layer 522, which part is the mount surface and is surrounded by the metallic reflecting plate 502.

It should be noted that the shape of the island electrode 508 is not particularly limited to those discussed in the present embodiment and may be a triangle, a quadrangle, a rectangle or the like. It is, however, preferable that the shape has rounded corners to avoid concentration of electric fields. It is possible to provide an element and/or a circuit on the island electrode 508 to adjust the conditions under which the LED chip is to drive. For example, a protection circuit element such as a Zener diode may be provided to limit current passing an LED chip. The foregoing also applies to the embodiments other than the present embodiment.

According to the present embodiment, the cathode electrode of the LED chip 501 is connected to the die-bonding-area/electrode section 507, and the anode electrode of the LED chip 501 is connected to the island electrode 508, as discussed above. It should be noted that the present embodiment is not limited to those discussed above. It is also possible to connect the anode electrode of the LED chip 501 to the die-bonding-area/electrode section 507 and connect the cathode electrode of the LED chip 501 to the island electrode 508.

The die-bonding-area/electrode section 507 and the island electrode 508 differ in electric potential, and the anode electrode and the cathode electrode of the LED chip 501 are each connected to the die-bonding-area/electrode section 507 and the island electrode 508 according to the design.

The insulating section 509 is made of RCC resin (resin coated copper), such as epoxy resin, and is formed so as to electrically isolate the island electrode 508 from the die-bonding-area/electrode section 507. A light reflective filler that reflects visible light rays having a wavelength in the range of 400 nm to 850 nm is added to the epoxy resin. It is preferable that an optical reflectance of the epoxy resin be 50% or above in the foregoing range of wavelength. Aluminum oxide, silicon oxide, titanium dioxide and the like, all of which are high in optical reflectance, are usable as the light reflective filler. Titanium dioxide is especially preferred because it has a high optical reflectance and is inexpensive.

However, use of titanium dioxide as the light reflective filler has a risk of oxidization of the metallic reflecting plate 502, the light-transmitting sealant 510, and/or the insulating section 509 due to photocatalytic reaction in the presence of oxygen during light emission operation (this oxygen originates from the atmosphere and/or moisture that have passed through the sealing resin, have been absorbed by peripheral components, and have stayed therein). On the other hand, when other reflective filler, such as aluminum oxide and silicon oxide, is used, the photocatalysis above does not occur. However, aluminum oxide and silicon oxide have hygroscopicity. Thus, there is a risk that the atmosphere and/or moisture absorbed in the process of sealing with the light-transmitting sealant 510 is vaporized by heat during light emission operation to cause the light-transmitting sealant 510 to peel off. It is preferable that the light-transmitting sealant 510 for sealing the LED chip 501 be excellent in light resistance and in hermetic property. However, a resin having a greater light resistance generally allows much gas, such as the atmosphere, to pass through, so that the atmosphere and/or moisture may come to a mount surface.

Accordingly, in a case in which the light reflective filler is to be added to the front layer close to the mount surface on which the LED chip 501 is mounted, it is especially preferable to reduce the amount of light reflective filler added. This makes it possible to improve the optical reflectance, and at the same time, reduce the amount of active oxygen for oxidization.

Thus, it is preferable that the insulating section 509 have a multilayer structure in which a light reflective filler-free resin layer that does not contain the light reflective filler and a resin layer that contains the light reflective layer are stacked in this order from a side via which light enters. Because epoxy resin absorbs light, it is preferable that the light reflective filler-free resin layer that does not contain the light reflective filler be formed in the shape of a layer as thin as possible, and that the light reflective filler-added resin layer that contains the light reflective filler be formed, as a lower layer, on a lower side of the light reflective filler-free resin layer that does not contain the light reflective filler.

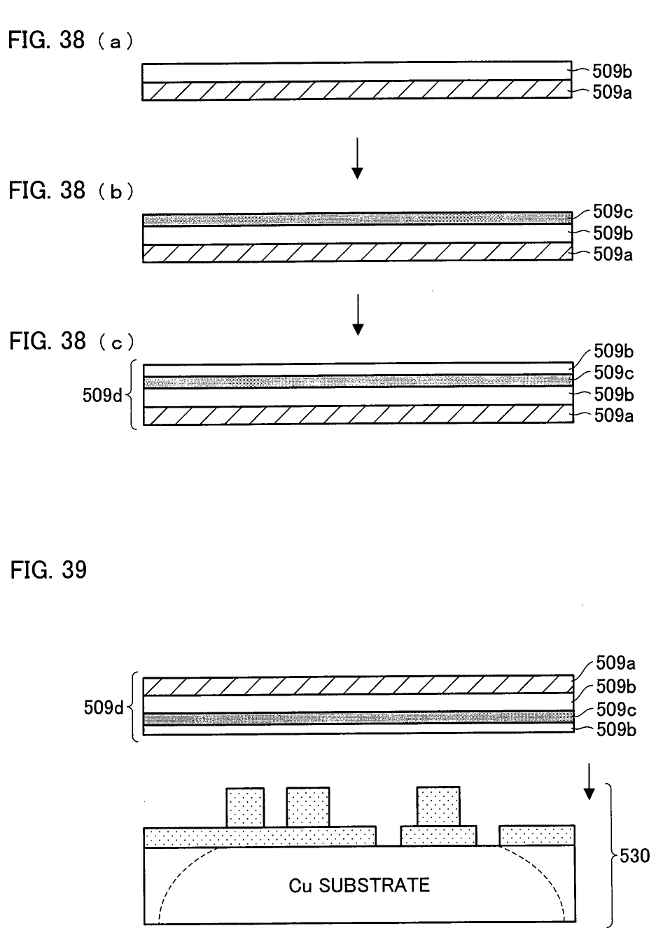

The following describes how the insulating section 509 is formed, with reference to FIGS. 38 to 41. First of all, as shown in FIG. 38(a), a liquid RCC resin is applied onto a Cu foil 509a called an RCC resin (resin coated copper) to form a layer (light reflective filler-free resin layer) 509b, which is slightly hardened and is in the form of a paste, with no titanium dioxide added. Then, as shown in FIG. 38(b), the liquid RCC resin with titanium dioxide added is applied onto the layer 509b to form a titanium dioxide-added resin layer 509c (light reflective filler-added resin layer), which is hardened and is in the form of a paste in the same manner. The resin layer 509c is hardened, and then the resin layer 509b is formed on the resin layer 509c, whereby a multilayer structure 509d as shown in FIG. 38(c) is formed.

The multilayer structure 509d formed through the foregoing process is then bonded to a rear surface (opposite to a surface via which light enters) of a metal plate 530, which includes the die-bonding-area/electrode section (first metal section) 507 and the island electrode (second metal section) 508, by thermal pressing, as shown in FIG. 39.

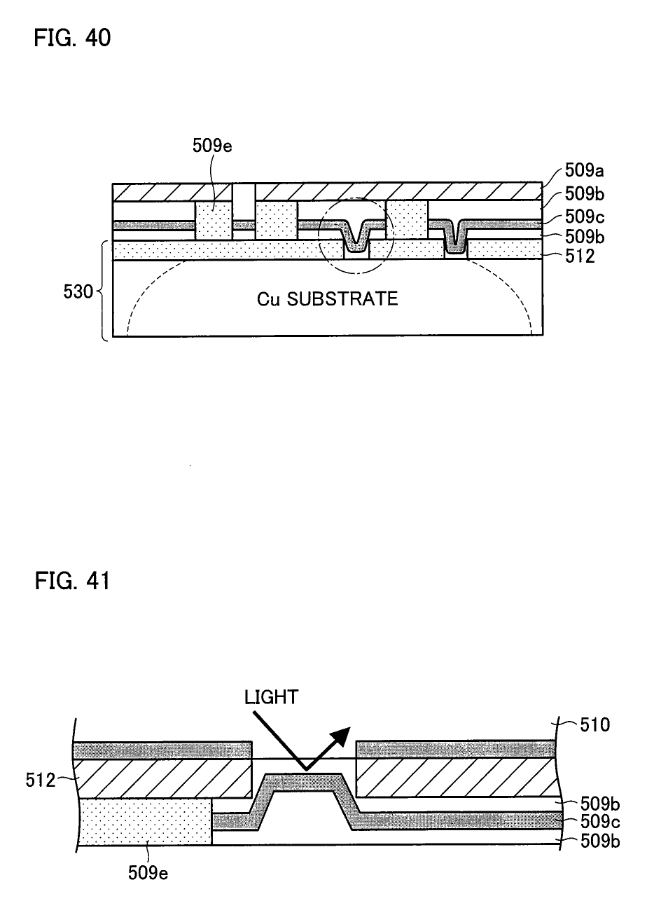

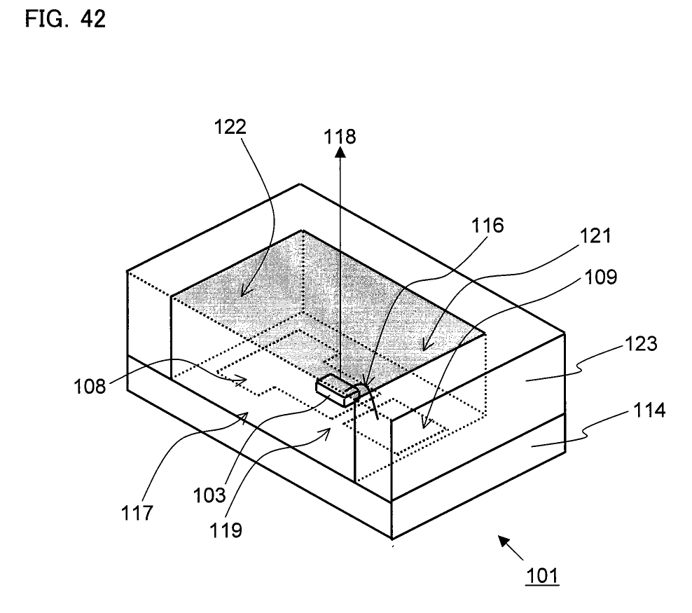

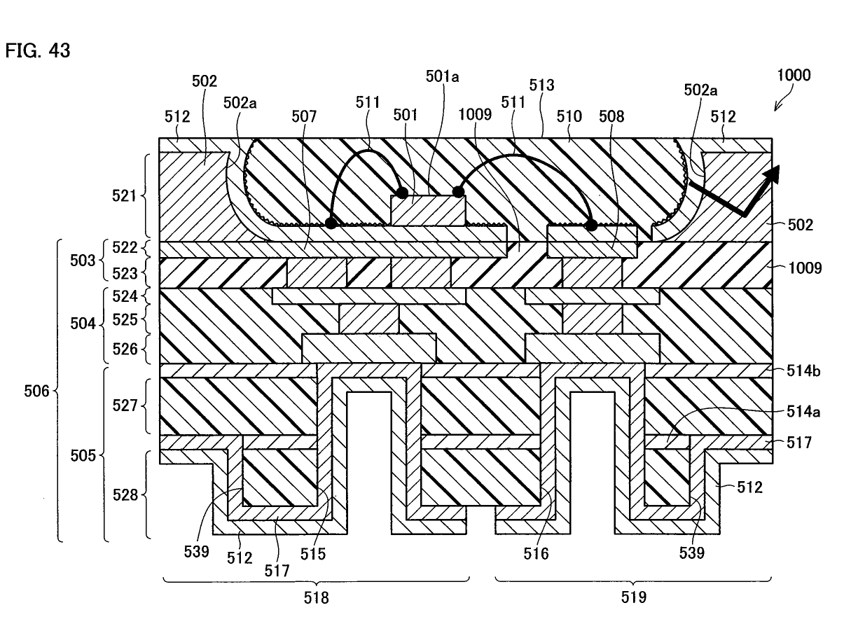

A surface of the copper foil 509a in the multilayer structure 509d in which the resin layer 509b, which does not contain titanium dioxide, and the resin layer 509c, which contains titanium dioxide, are stacked is polished, and a part thereof is connected to a conductive layer (Cu post layer) 509e, as shown in FIG. 40.

To add a light reflective filler, such as titanium oxide, to a resin, the light reflective filler is mixed in a liquid RCC resin. In a single layer of resin, the light reflective filler precipitates due to the difference from the RCC resin in specific gravity and sinks toward the Cu foil 509a. Thus, it is difficult to adjust the position of the resin layer containing the light reflective filler (reflective filler-added resin layer) 509c. Accordingly, first, the resin layer (reflective filler-free resin layer) 509b is formed on the copper foil 509a, which is to be connected to the conductive layer 509e, and the resin layer (reflective filler-added resin layer) 509c containing the light reflective filler is formed on the resin layer 509b and hardened, and then the RCC resin that does not contain the light reflective filler is applied again to the resin layer 509c to form the resin layer (reflective filler-free resin layer) 509b, whereby it becomes possible to avoid a surface of the mount surface containing the reflective filler. The RCC resin thus formed is bonded, as described above, to the rear surface of the metal plate 530, on which both the die-bonding-area/electrode section 507 and the island electrode 508 are formed, and then is thermally pressed, whereby the insulating section 509 is formed. Thereafter, the following processing is carried out, but detailed description thereof is omitted. In a lower layer of the insulating section 509, multi-layers of conductive layers and resin layers are provided flat in such a manner that electric potential of the die-bonding-area/electrode section 507 and electric potential of the island electrode 508 are passed through the conductive layer 509e to the rear surface of the substrate, and at the same time, the die-bonding-area/electrode section 507 and the island electrode 508 are kept isolated from each other. A glass epoxy substrate having through holes is bonded, and a rear electrode is provided so as to conduct electricity to the conductive layer through the through holes. Finally, the front surface of the metal plate is etched to form a reflector plate in such a manner that the insulating section 509 is exposed from the mount surface.

FIG. 41 is an enlarged sectional view showing the encircled portion in FIG. 40.

The RCC resin containing the light reflective filler is used in the insulating section 509 so that, as shown in FIG. 41, the light reflective filler is allowed to reflect light that is emitted from the LED chip 501 and enters the insulating section 509 and light that is emitted from a fluorescent material contained in the light-transmitting sealant 510, which seals the LED chip 501, and enters the insulating section 509. This makes it possible to reduce light that is partially absorbed and becomes attenuated when entering the insulating section 509 and being reflected by a peripheral component, so that efficiency for light utilization and heat releasing property improve.

Further, even if titanium dioxide is used as the light reflective filler, the intensity of light emitted from a light outgoing surface is improved while a problem of oxidization of the metallic reflecting plate 502, the light-transmitting sealant 510, and the insulating section 509 due to photocatalytic reactions of the light reflective filler in the presence of oxygen and a problem of peel-off of the light-transmitting sealant 510 are restrained, compared with the structure in which titanium dioxide is added to the entire part of the insulating section 509.

That is to say, it becomes possible to reduce the amount of light absorbed by the insulating section 509 and the amount of light that passes through the substrate and is emitted from the rear surface to the outside, so that the efficiency for light utilization and heat releasing property are improved.

Further, it is preferable that the RCC resin be formed by thermal processing in an atmosphere of inert gas. This makes it possible to prevent resin used in the insulating section 509 from deteriorating (changing to yellow), so that the foregoing effect is produced efficiently without absorption of light by the resin having deteriorated.

The atmosphere and/or moisture are likely to enter the mount surface especially when resin is put into the light-transmitting sealant 510 during a process step of sealing the light-transmitting sealant 510. If the application of heat for hardening is carried out in this state, the insulating section (RCC resin) 509 on the mount surface is oxidized by the atmosphere and/or moisture present inside. Therefore, it is preferable that a process step of applying heat to harden the light-transmitting sealant 510 be carried out in an atmosphere of inert gas.

According to the present embodiment, a boundary surface between the insulating section 509 and the die-bonding-area/electrode section 507 forms a straight line when viewed from a direction perpendicular to the light emitting surface 501a of the LED chip 501, as shown in FIG. 2. It is preferable in view of efficiency for light utilization that the insulating section 509 surrounding the island electrode 508 be formed as small as possible in a part of the mount surface, which part is surrounded by the metallic reflecting plate 502, to raise the proportion of the die-bonding-area/electrode section 507 serving as a mount surface metallic reflecting film.

In summary, the die-bonding-area/electrode section 507, which is provided so as to be combined with the metallic reflecting plate 502 and is separated from the island electrode 508 by the insulating section 509 sandwiched by the die-bonding-area/electrode section 507 and the island electrode 508, and the island electrode 508, which is formed so as to be surrounded by the insulating section 509, are formed in the second layer 522.

The third layer 523 is provided to electrically connect the second layer 522 and the fourth layer 524, which will be described later. The third layer 523 also has a function to improve the degree of adherability of the insulating section 509 at the time of forming the insulating section 509 in the second layer 522.

To avoid contact with moisture and the air, it is preferable not to contain the light reflective filler, such as titanium dioxide, in proximity to the boundary surface that is to be bonded to other components via the third layer 523 serving as the bonding layer. Because the boundary surface separating from the bonding layer or from the other components is likely to hold moisture and/or the air, it is preferable not to bring the light reflective filler into contact. Further, resin that allows little gas such as the atmosphere to pass therethrough, such as epoxy resin, is commonly used in the insulating section 509 to which titanium dioxide is to be added. It is thus especially preferable to provide the titanium dioxide-added resin layer 509c inside of the resin of the insulating section 509.

When the die-bonding-area/electrode section 507 and the island electrode 508e have been formed on a patterned surface but the insulating section 509 has not been formed thereon yet, the patterned surface is in a state in which only an external edge of the die-bonding-area/electrode section 507 and an external edge of the island electrode 508 have etched thickness (unevenness). In this case, although an insulative material having the same thickness as the etched thickness is bonded to the patterned surface and pressed to form the insulating section 509, there is a possibility that the insulative material peels off because a surface to which the insulative material is bonded is a flat surface.

In view of this circumstance, the third layer 523 including, inside the etched outer edge of the second layer 522, conductive sections 531 and 532 each having etched outer edges is added, whereby a contact area with the insulating section 509 increases to improve adhesion of the insulating section 509.

To reliably isolate the anode and the cathode, the conductive section 532 immediately below the area where the island electrode 508 is formed needs to be formed smaller than the island electrode 508.

The following describes a structure of the middle layer 504.

The middle layer 504 has a triple-layer multilayer structure in which the fourth layer 524, the fifth layer 525, and the sixth layer 526 are stacked in this order from the mount surface. The middle layer 504 electrically connects the third layer 523 with respective electrode sections provided in through holes 515 and 516 formed in the fifth layer 525 and in the sixth layer 526. The through holes 515 and 516 will be described later.

The fourth layer 524 is formed in such a manner that a conductive section 533, which is electrically connected to the die-bonding-area/electrode section 507, and a conductive section 534, which is electrically connected to the island electrode 508, do not come into contact with each other. The conductive section 533 is formed so as to entirely cover a part of the third layer 523, in which part the conductive section 531 is formed. In the same manner, the conductive section 534 is formed so as to entirely cover a part of the third layer 523, in which part the conductive section 532 is formed. The conductive section 533 and the conductive section 534 are formed in such a manner that a margin for dicing is left to prevent damages due to a burr occurred at the time of dicing the light emitting device 500.

The fifth layer 525 is formed in such a manner that a conductive section 535, which is electrically connected to the die-bonding-area/electrode section 507, and a conductive section 536, which is electrically connected to the island electrode 508, do not come into contact with each other.

The sixth layer 526 is formed in such a manner that a conductive section 537, which is electrically connected to the die-bonding-area/electrode section 507, and a conductive section 538, which is electrically connected to the island electrode 508, do not come into contact with each other.

The conductive section 537 and the conductive section 538 are wider than the through hole 515 and the through hole 516, respectively, in a plane direction of the through hole 515 and the through hole 516 and are formed so as to cover the through hole 515 and the through hole 516, respectively, so that, when the through hole 515 and the through hole 516 are being plated with copper plating 517, no copper is leaked from the through holes 515 and 516 through a gap.

The Following Describes the Rear Layer 505.

The rear layer 505 has a dual-layer multilayer structure in which the seventh layer 527 and the eighth layer 528 are stacked in this order from the mount surface. The seventh layer 527 and the eighth layer 528 are each made of a laminated base material, such as a glass epoxy substrate, and are stacked with an adhesive tape 514a.

The through hole 515 and the through hole 516 are formed in the rear layer 505 having the dual-layer structure including the seventh layer 527 and the eighth layer 528. Wiring to the cathode electrode connected to the die-bonding-area/electrode section 507 and wiring to the anode electrode connected to the island electrode 508 are formed through the through hole 515 and the through hole 516, respectively. The through hole 515 and the through hole 516 are formed in a lower layer and below the die-bonding-area/electrode section 507 and the island electrode 508, respectively.

The through hole 515 and the through hole 516 are both formed by drill processing in such a manner that a distance from a center c1 of the mount surface to the through hole 515 is equal to a distance from the center c1 of the mount surface to the through hole 516 (d1=d2) so that the anode and the cathode have a same thermal capacity.

A reason therefor is that, if an anode side and cathode side of the rear electrode differ in area and thus differ in thermal capacity, solder does not melt uniformly when soldering is conducted to connect the rear electrode (rear electrodes 518 and 519, which will be described later) and an external electrode. This causes defective soldering.

Further, the anode electrode and the cathode electrode on a rear surface of the multilayer substrate 506 are separated in such a manner that the distance from the center c1 of the mount surface to the anode electrode is equal to the distance from the center c1 of the mount surface to the cathode electrode (d3=d4). It is possible to determine respective diameters of the through hole 515 and the through hole 516 according to design in such a manner as to leave the dicing margin and to avoid defective plating.

Accordingly, the rear layer 505 constituted of a laminate of the seventh layer 527 and the eighth layer 528 is adhered to the sixth layer 526 with an adhesive tape 514b by pressing. The through holes 515 and 516 are formed so as to be covered by the conductive sections 537 and 538 of the sixth layer 526, respectively.

In this state, respective inner surfaces of the through holes 515 and 516 are plated with the copper plating 517. Further, the conductive sections 537 and 538 of the sixth layer 526 are adhered so as to cover the through holes 515 and 516, respectively. Thus, respective parts of the conductive sections 537 and 538 of the sixth layer 526, which parts are respectively exposed inside the through holes 515 and 516, are also plated with the copper plating.

The copper plating 517 is also formed on a lower surface of the eighth layer 528. The copper plating 517 between the through holes 515 and 516 is etched. As a result, the rear electrode 518, which is to be electrically connected to the die-bonding-area/electrode section 507, and the rear electrode 519, which is electrically connected to the island electrode 508, are formed. The rear electrodes 518 and 519 are plated with the silver plating 512 when a surface 502a, which is an inner surface of the metallic reflecting plate 502 described later, is plated with the silver plating 512.

The metallic reflecting plate 502 is arranged in such a manner as to reflect light emitted from the light emitting surface 501a of the LED chip 501 and to guide the light to the light outgoing surface 513. The metallic reflecting plate 502 is made of copper and is formed, on the mount surface of the substrate, in such a way as to surround the LED chip 501 and the island electrode 508 and to be combined with the multilayer substrate 506. Specifically, the metallic reflecting plate 502 is formed so as to be combined with the die-bonding-area/electrode section 507 in such a manner that a part of the die-bonding-area/electrode section 507 is exposed inside of the metallic reflecting plate 502.

As shown in FIG. 2, the metallic reflecting plate 502 is formed in such a manner that the surface 502a, which is an inner side surface of the metallic reflecting plate 502, has a curved cross-section in the laminate direction.

The inner side of the metallic reflecting plate 502 is shaped by etching the metallic reflecting plate that is substantially in the shape of a rectangular parallelepiped. It is also possible to shape the inner side of the metallic reflecting plate 502 by pressing a metal foil to form a recess and then etching the recess. Since the recess that is already formed is etched, it is possible to shape the inner side of the metallic reflecting plate 502 more easily.

An outer side of the metallic reflecting plate 502 is shaped by wet etching so that a cross section vertical to the multilayer substrate 506 is shaped into a gentle curve. Specifically, the outer side of the metallic reflecting plate 502 is curved gently from an upper end to a bottom end with distance from the LED chip 501.

The light-transmitting sealant 510 is formed so as to seal an inner space surrounded by the multilayer substrate 506 and the metallic reflecting plate 502. The light-transmitting sealant 510 is made of resin, and silicone is used in the present embodiment. Light emitted from the light emitting surface 501a of the LED chip 501 outgoes from the light outgoing surface 513 provided on a side of the light-transmitting sealant 510, from which side light is to outgo.

An upper surface of the metallic reflecting plate 502 and the surface 502a, which is the inner side surface of the metallic reflecting plate 502, are plated with the silver plating 512. Silver is significantly high in reflectance of blue light. Therefore, with the silver plating 512 provided, light emitted from the LED chip 501 is efficiently reflected and guided to the light outgoing surface 513.

The light-transmitting sealant 510 has a function to protect the LED chip 501, the wire 511, and the silver plating 512.

As described above, the metallic reflecting plate 502 is plated with the silver plating 512, which is high in reflectance of blue light, to efficiently reflect light emitted from the LED chip 501. However, since silver is highly reactive, it easily changes in color and deteriorates owing to corrosive gas or the like. Thus, the light-transmitting sealant 510 is provided to protect the silver plating 512 so that the silver is prevented from reacting or peeling off even if the conditions are adverse.

In the present embodiment, an upper end section, in a direction in which the LED chip 501 emits light, of a space surrounded by the mount surface and the metallic reflecting plate 502 is opened to form a light outgoing surface 513. The space is filled with the light-transmitting sealant 510, as described above. A middle part of the space between the light outgoing surface 513 (upper-end opening section) and the mount surface, which is the bottom surface, has a widest cross section in a planar direction. The cross section is wider than the greatest width of the light outgoing surface 513 in the planar direction. That opening is narrowed from the middle part to the light outgoing surface 513.

Further, the inner side surface 502a of the metallic reflecting plate 502, which surface 502a is plated with the silver plating 512, is processed so as to become scabrous. A part of an inner side surface of the die-bonding-area/electrode section 507, which part is plated with the silver plating 512 and is in contact with the light-transmitting sealant 510, is also processed so as to become scabrous. A part of an inner side surface of the island electrode 508, which part is plated with the silver plating 512 and is in contact with the light-transmitting sealant 510, is also processed so as to become scabrous.

A preferred shape of the scabrous surface is a shape formed of a sequence of sharp crests and troughs. Various conventionally-used methods are employable to make the surfaces scabrous. For example, an etchant and/or an etching condition are changed to a different etchant and/or a different etching condition during a process of forming the metallic reflecting plate 502 by etching or the following process of etching to remove a nickel layer (not illustrated) between the metallic reflecting plate 502 and the second layer 522 from the mount surface, whereby the surface of the metallic reflecting plate 502 becomes scabrous.

As described above, the silver plating 512 is highly reactive and easily deteriorates and becomes corroded. Thus, it is necessary to protect the silver plating 512 to prevent the silver plating 512 from peeling off and deteriorating. In the present embodiment, the foregoing structure is adapted so that the light-transmitting sealant 510 adheres to the silver plating 512 more firmly, whereby the light transmitting sealant 510 functions better as a protection film.

Further, the light-transmitting sealant 510 contains fluorescent material. This allows blue light emitted from the LED chip 501 to be converted into yellow light in the light-transmitting sealant 510. Therefore, it is possible to emit white light from the light outgoing surface 513 by a combination of the blue light emitted from the LED chip 501 and the yellow light emitted from the fluorescent material.

Ways to obtain white light from blue light emitted from the LED chip 501 include a method using the yellow fluorescent material as described above and a method using a combination of a green fluorescent material and a red fluorescent material. The combination of the green fluorescent material and the red fluorescent material causes light rays to be mixed, whereby white light is obtainable.

The following discusses a direction in which light emitted from the LED chip 501 travels in the light emitting device 500 having the foregoing structure.

The light emitted from the light emitting surface 501a of the LED chip 501 is desired to be emitted from the light outgoing surface 513 efficiently without a loss. Basically, as described above, the intensity of light emitted from the light emitting surface 501a of the LED chip 501 becomes maximum in an upward direction vertical to the light emitting surface 501a. The light outgoing surface 513 of the light-transmitting sealant 510 is provided so as to face the light emitting surface 501a of the LED chip 501. This is a most suitable position of the light outgoing surface 513.

To be exact, however, the light emitted from the light emitting surface 501a of the LED chip 501 in all directions. Furthermore, a wavelength of the light is changed by the fluorescent material while the light passes through the light-transmitting sealant 510, and the light thus changed is scattered and then emitted. Accordingly, the light travels in a direction within 180 degrees.

The metallic reflecting plate 502 has a continuous shape surrounding all edges. Therefore, light traveling in the direction of the metallic reflecting plate 502 is reflected by the surface 502a of the metallic reflecting plate 502 without leaking from the metallic reflecting plate 502 to the outside. The light is reflected once or for plural times and then emitted from the light outgoing surface 513 of the light-transmitting sealant 510.

The fluorescent material has a tendency to sink to the bottom. Therefore, the fluorescent material tends to sink to the substrate in the light-transmitting sealant 510. With the light emitting device 500 of the present embodiment, light is reflected by the metallic reflecting plate 502 so that it is possible to let the light travel in the direction of the substrate. Therefore, efficient use of the fluorescent material becomes possible.

All light rays emitted from the LED chip 501 do not always reach the light outgoing surface 513. Some of the light rays sometimes travel in the direction of the multilayer substrate 506. The following describes in detail a path of light in this case.

If being made of resin, the multilayer substrate 506 allows light to pass through because the resin transmits light. A possible measure to this circumstance is to form metal on a layer of the multilayer substrate to reduce light that is transmitted to leak in the laminate direction (i.e. the laminate direction toward a side opposite to the side where the light emitting surface 501a is provided).

However, the light emitting device 500 is to be divided by dicing at the end of the manufacturing process. On an end surface formed as a result of the dicing, respective end sections of the layers are exposed. Therefore, light having traveled through the layers is emitted from the end surface.

Specifically, when a package of the light emitting device 500 is substantially a rectangular parallelepiped, has the center of gravity at the LED chip 501, and has the light outgoing surface 513 as a surface, light leaks from four surfaces each forming an angle of 90 degrees with the outgoing surface 513.

In the present embodiment, the die-bonding-area/electrode section 507 and the island electrode 508 are formed as follows to prevent light from leaking. The die-bonding-area/electrode section 507 and the island electrode 508 are formed on the mount surface surrounded by the metallic reflecting plate 502. The island electrode 508 is formed so as to be surrounded by the insulating section 509. The die-bonding-area/electrode section 507 is formed widely in an area outside the insulating section 509.

Light having leaked from the light emitting device becomes stray light. When the light emitting device is built in as a light source such as a backlight of a liquid crystal panel, the stray light becomes unnecessary light that is not needed for a display on the liquid crystal panel. Even if the unnecessary light is removed in a light source section, a loss of light is produced. Therefore, the light emitted from the LED chip is not used efficiently.

Furthermore, the stray light is absorbed by other components outside of the light emitting device. This overall causes a big loss of energy. Therefore, the light emitted from the LED chip is not used efficiently.

Metal reflects light. Therefore, when light travels in the direction of the multilayer substrate 506, the light does not pass through the multilayer substrate 506 but is reflected because an area of the mount surface surrounded by the metallic reflecting plate 502, on which area metal is provided, is increased. This makes it possible to increase light that travels in the direction of the light outgoing surface 513. It also becomes possible to further reduce light that travels to an inner part of the multilayer substrate 506.

The light emitting device 500 of the present embodiment is formed in such a manner that the metallic reflecting plate 502, which reflects the light from the LED chip 501 to guide the light to the light outgoing surface 513 provided in the direction in which the light is emitted, is provided in the direction in which the LED chip 501 emits light, and that the metallic reflecting plate 502 is provided so as to surround the LED chip 501 entirely. This allows the metallic reflecting plate 502 to reflect light emitted from the LED chip 501 to its surrounding area to efficiently guide the light to the light outgoing surface 513. It thus becomes possible to reduce leakage of light from a side surface of the light emitting device 500 so that the intensity of light emitted from the light outgoing surface 513 improves.

The die-bonding-area/electrode section 507, which serves as a mount-surface metallic reflecting film, is formed in an area of the mount surface, which area is surrounded by the metallic reflecting plate 502 and is not an area where the insulating section 509 is formed to isolate the island electrode 508 from the die-bonding-area/electrode section 507. This allows much of light emitted from the LED chip 501 and traveling toward the substrate to be reflected by the die-bonding-area/electrode section 507 to be guided toward the light outgoing surface 513. Thus, it becomes possible to reduce the amount of light absorbed by the substrate and the amount of light passing through the substrate to escape to the outside via the rear surface, so that the intensity of light emitted from the light outgoing surface improves.

Further, in the light emitting device 500 of the present embodiment, the LED chip 501 emits light. This generates heat in the LED chip 501. The LED chip 501 is mounted on the die-bonding-area/electrode section 507, which is formed widely, and the die-bonding-area/electrode section 507 is formed so as to be combined with the metallic reflecting plate 502. Therefore, the light emitting device 500 according to the present embodiment is excellent in heat releasing property, and problems of damage to an element or components constituting the element due to heat are reduced with the light emitting device 500 according to the present embodiment.

Further, silicone used in the light-transmitting sealant 510 of the light emitting device 500 has weak adhesion property. Therefore, the light-transmitting sealant 510 may peel off if it is simply bonded to a flat surface.

In the light emitting device 500 of the present embodiment, the opening section of the metallic reflecting plate 502, which opening section forms the light outgoing surface 513 and is made at an upper end in the direction in which light is emitted, is made narrower than the middle part between the opening section and the bottom surface section, which is on the mount surface, as described above. This prevents the light-transmitting sealant 510 from peeling from the light emitting device 500.

Further, the inner side surface of the metallic reflecting plate 502, which surface is plated with the silver plating 512 and is in contact with the light-transmitting sealant 510, is made scabrous. The contact area where the light-transmitting sealant 510 and the metallic reflecting plate 502 are in contact with each other is increased so that the degree of adhesion between the light-transmitting sealant 510 and the metallic reflecting plate 502 improves, whereby the problem of peeling of the light-transmitting sealant 510 is reduced.

It is preferable that, as shown in FIG. 2, at least the rear electrode 519 be formed so as to entirely cover an area that corresponds, in the laminate direction, to the area where the insulating section 509 is formed so as to surround the island electrode 508. This makes it possible to prevent the light, emitted from the LED chip 501 and travels from the mount surface toward the inner part of the substrate, from passing through the substrate via the insulating section 509 to escape to the outside of the element via the rear surface. Thus, the intensity of the light emitted from the light outgoing surface 513 improves.

The light having passed through the multilayer substrate 506 is reflected in the foregoing manner so that the light is prevented from reaching the outside. This makes it possible to reduce the leakage of light.

The island electrode 508 is connected to the rear electrode 519 via the conductive section 534 provided to the fourth layer 524. It is preferable that the conductive section 534 be formed so as to cover all over an area corresponding, in the laminate direction, to an area where the insulating section 509 is formed.

Forming the insulating section 509 so as to be covered with the conductive section 534, which is formed closer to the mount surface of the substrate than to the rear electrode 519, makes it possible to more effectively reduce the amount of light leaking to the outside of the element through the insulating section 509 via the rear surface.

Further, it is preferable that the conductive section 534 have a size enough to cover the insulating section 509 formed within an outer edge of the metallic reflecting plate 502 so as to surround the island electrode 508, and that the conductive section 534 be provided to cover the insulating section 509. This makes it possible to reflect light having passed through the multilayer substrate 506, whereby the light is prevented from reaching the rear layer 505. Thus, it becomes possible to reduce more leakage of light.

Further, a notch 539 is formed in each corner of the eighth layer 528 of the multilayer substrate 506. The notch 539 is also plated with the copper plating 517.

With this structure, the copper plating formed on the notch 539 is also diced when the light emitting device 500 is diced at the end. This causes the copper plating on a diced side surface to form a burr. A metal thread arising from the burr sometimes comes into contact with the metallic reflecting plate 502 to cause a short-circuit.

Thus, the metallic reflecting plate 502 is arranged in such a manner that the widest part of the outer side surface comes inside an area where the notch 539 is formed, whereby it becomes possible to prevent short-circuit discussed above from occurring.

Concretely, since a maximum length of the metal thread is equal to the thickness of the rear layer 505, it is preferable to arrange as shown in the following formula

A>C−B,

where A is a distance between the notch 539 and the widest part of the outer side surface of the metallic reflecting plate 502, B is the thickness between the metallic reflecting plate 502 and the rear layer 505 (thickness between the second layer 522 and the seventh layer 527), and C is the thickness of the rear layer 505.

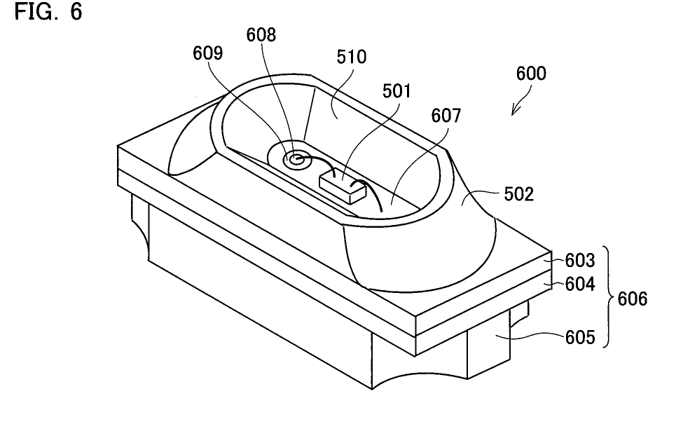

Further, it is possible to determine the opening section of the metallic reflecting plate 502 and the shape of the outer side surface of the metallic reflecting plate 502 according to a shape and a design that are easy to etch. FIG. 4 shows a metallic reflecting plate 541 having a different outer shape. FIG. 5 shows a metallic reflecting plate 542 and an opening section 543 each having a different outer shape.

Further, it is preferable that an outer dimension of the light emitting device be as small as possible to meet the demands for smaller light sources. On the other hand, to keep a light emitting surface area of the light source, it is preferable that the opening section of the metallic reflecting plate 502 be formed as large as possible while the element is reduced in size.

### Second Embodiment

The following describes an embodiment of the present invention, with reference to FIGS. 6-14 and 23-26. For the convenience of explanation, components having the same functions as those of the components shown in the figures of the foregoing embodiments are given the same reference numbers, and description thereof is omitted.

A light emitting device 600 of the present embodiment produces an excellent effect of preventing light from leaking, in addition to the advantageous effects that the light emitting device 500 of First Embodiment produces. Further, the number of layers in a multilayer substrate 606 is reduced. The following description focuses on the structure that produces the advantageous effects and how it works to produce the advantageous effects.

In the light emitting device 500 of First Embodiment, a boundary surface between an insulating section 509 and a die-bonding-area/electrode section 507 forms a straight line when viewed from a direction vertical to a light outgoing surface.

In the present embodiment, an insulating section 609, which electrically isolates an island electrode 608 from the die-bonding-area/electrode section 607, is formed, within a mount surface surrounded by a metallic reflecting plate 502, in the shape of a ring so as to surround an outer edge of the island electrode 608, as shown in FIGS. 6, 7, and 23. This makes it possible to isolate the island electrode 608, with a smaller area, from the die-bonding-area/electrode section 607.

The die-bonding-area/electrode section 607 is formed so as to surround the insulating section 609, which electrically isolates the island electrode 608 from the die-bonding-area/electrode section 607. Thus, the die-bonding-area/electrode section 607 is present between the insulating section 609 and the metallic reflecting plate 502. Therefore, even if positional deviation occurs during a process of forming the metallic reflecting plate 502, the deviation does not affect the shape or the area of the insulating section 609. Thus, the amount of light leaking through the insulating section 609 does not vary. Further, it also becomes possible to set a shortest separation distance to isolate the metallic reflecting plate 502 from both the die-bonding-area/electrode section 607 and the second island electrode 608 without paying attention to alignment deviation in the processing, and to design the insulating section 609 with a smallest area. This makes it possible to more effectively prevent light from leaking from the insulating section 609, so that the light traveling from the metallic reflecting plate 502 toward the substrate is reflected by the mount-surface metallic reflecting film toward the light outgoing surface 513 more efficiently. Thus, efficiency for light utilization and heat releasing property further improve.

In other words, it is possible to widely and entirely form, within an area of the mount surface, which area is surrounded by the metallic reflecting plate 502, the die-bonding-area/electrode section 607, which serves as the mount-surface metallic reflecting film, in such a manner as to surround the island electrode 608 via the insulating section 609. Thus, it is possible to further reduce the amount of light absorbed by the substrate and the amount of light passing through the substrate to leak to the outside via the rear surface, compared with the structure of First Embodiment.

FIG. 6 is an oblique perspective view showing an exemplary structure of the light emitting device 600 of the present embodiment.

As shown in FIG. 6, the light emitting device 600 according to the present embodiment includes an LED chip 501, the metallic reflecting plate 502, multilayer substrate 606 (front layer 603, middle layer 604, and rear layer 605), and a light-transmitting sealant 510.

The front layer 603 includes the die-bonding-area/electrode section (first metal section) 607, the island electrode (second metal section) 608, and the insulating ring (second insulating section) 609.

As described above, the insulating ring 609 is formed in the shape of a ring (shape of a doughnut) so as to surround an outer edge of the island electrode 608. Thus, even if the die-bonding-area/electrode section (first metal section) 607 serving as the mount-surface metallic reflecting film is widely and entirely formed within the area of the mount surface, which area is surrounded by the metallic reflecting plate 502, in such a manner as to surround the outer edge of the island electrode 608 via the insulating ring 609, it is still possible to isolate the island electrode 608 from the remaining part of the area. This allows much of light emitted from the LED chip 501 and traveling toward the substrate to be reflected by the mount-surface metallic reflecting film to be guided toward the light outgoing surface 513 provided in the direction in which light is emitted. Thus, it becomes possible to reduce the amount of light absorbed by the substrate and the amount of light passing through the substrate to escape to the outside of the element via the rear surface, so that the intensity of the light emitted from the light outgoing surface 513 improves.

The insulating ring 609 is made of RCC resin such as epoxy resin, in the same manner as the insulating section 509 of First Embodiment. The RCC resin contains a light reflective filler that reflects a visible light ray having a wavelength in the range of 400 nm to 850 nm. It is preferable that an optical reflectance of the RCC resin be 50% or above with respect to the wavelength in the range mentioned above. Aluminum oxide, silicon oxide, titanium dioxide, or the like, all of which have a high optical reflectance, is usable as the light reflective filler. The titanium dioxide is especially preferred because it has a high optical reflectance and is inexpensive.

However, the use of titanium dioxide as the light reflective filler has a risk of oxidization of the metallic reflecting plate 502, the light-transmitting sealant 510, and/or the insulating ring 609 due to photocatalytic reaction in the presence of oxygen during light emission operation (oxygen comes from the atmosphere and/or moisture having passed through the sealing resin, having been absorbed by the peripheral components, and having stayed inside). On the other hand, the use of other reflective filler such as aluminum oxide and silicon oxide does not cause the photocatalysis. However, aluminum oxide and silicon oxide have hygroscopicity. Thus, there is a risk that the atmosphere and/or moisture absorbed in the process of sealing with the light-transmitting sealant 510 is vaporized by heat during light emission operation to cause the light-transmitting sealant 510 to peel off. It is preferable that the light-transmitting sealant 510 for sealing the LED chip 501 be excellent in light resistance and hermeticity. However, in general, resin having better light resistance transmits gas such as the atmosphere more easily, so that there is a possibility that the atmosphere/moisture reaches the mount surface.

Thus, when the light reflective filler is to be added only to the front layer near the mount surface of the LED chip 501, it is especially preferable to reduce the amount of light reflective filler added so that the optical reflectance improves while the amount of active oxygen to be oxidized is reduced.

Accordingly, it is preferable that the insulating ring 609 have a multilayer structure in which a light reflective filler-free resin layer containing no light reflective filler and a light reflective filler-added resin layer containing the light reflective filler are stacked in this order from a side via which light enters. Epoxy resin absorbs light. Thus, it is preferable to form the light reflective filler-free resin layer, which does not contain the light reflective filler, in the form of a layer as thin as possible and then to form the light reflective filler-added resin layer, which contains the light reflective filler, in a lower layer on the light reflective filler-free resin layer.

The process of forming the insulating ring 609 is same as the process of forming the insulating section 509 of First Embodiment discussed above. Therefore, description thereof is omitted here.

The use of the RCC resin, containing the light reflective filler, in the insulating ring 609 allows the light reflective filler to reflect the light that is emitted from the LED chip 501 and enters the insulating ring 609 and the light that is emitted from the fluorescent material contained in the light-transmitting sealant 510, which seals the LED chip 501, and enters the insulating ring 609. This makes it possible to reduce light that is partially absorbed and becomes attenuated when entering the insulating ring 609 and being reflected by the peripheral components. Thus, efficiency for light utilization and heat releasing property improve.

It is also possible with the use of titanium dioxide as the light reflective filler to improve the intensity of light emitted from the light outgoing surface while preventing the problem of oxidization of the metallic reflecting plate 502, the light-transmitting sealant 510, and/or the insulating ring 609 in the presence of oxygen due to photocatalytic reaction of the light reflective filler and the problem of peel-off of the light-transmitting sealant 510, compared with the case in which the light reflective filler is added all over the insulating ring 609.

In other words, it is possible to reduce the amount of light absorbed by the insulating ring 609 and the amount of light passing through the substrate to be emitted to the outside via the rear surface. Thus, efficiency for light utilization and heat releasing property improve.

It is preferable that the RCC resin be formed by thermal processing in an atmosphere of inert gas. This makes it possible to prevent resin used in the insulating ring 609 from deteriorating (changing to yellow), so that the foregoing effect is produced efficiently without absorption of light by the resin having deteriorated.

With the light emitting device 600 according to the present embodiment, the area where the resin having low heat releasing property is reduced, and the die-bonding-area/electrode section 607 serving as the mount-surface metallic reflecting film is formed widely, whereby the heat releasing property also improves.

Further, in the same manner as in First Embodiment, the die-bonding-area/electrode section 607 is formed so as to be combined with the metallic reflecting plate 502. This allows heat generated in the metallic reflecting plate 502 to be released to the outside efficiently.

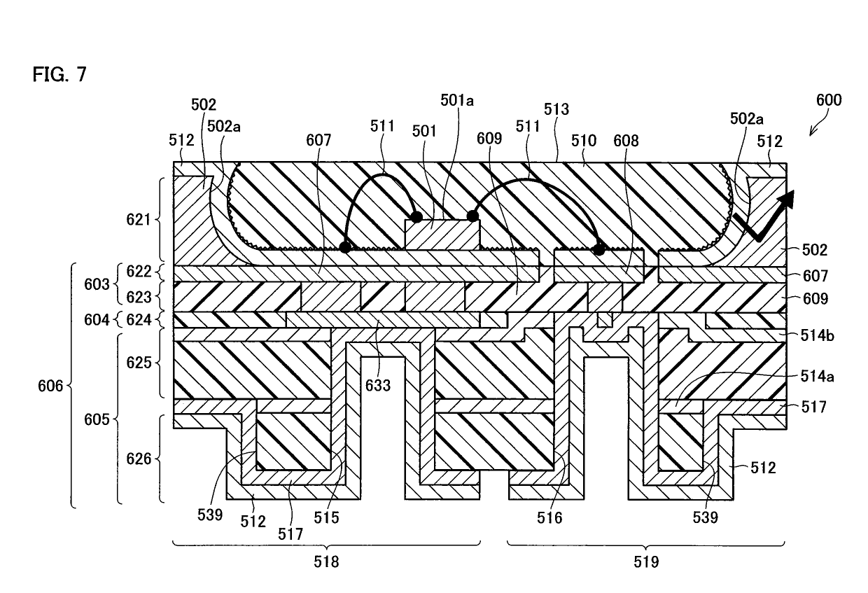

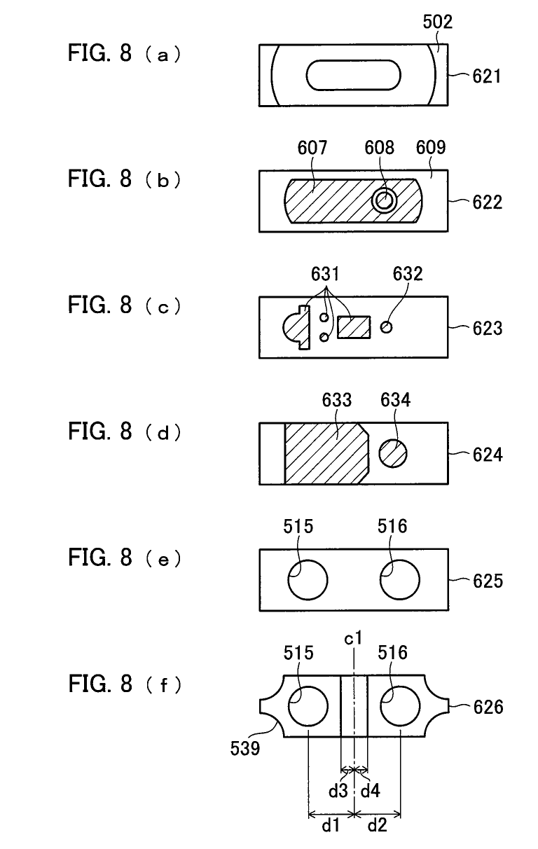

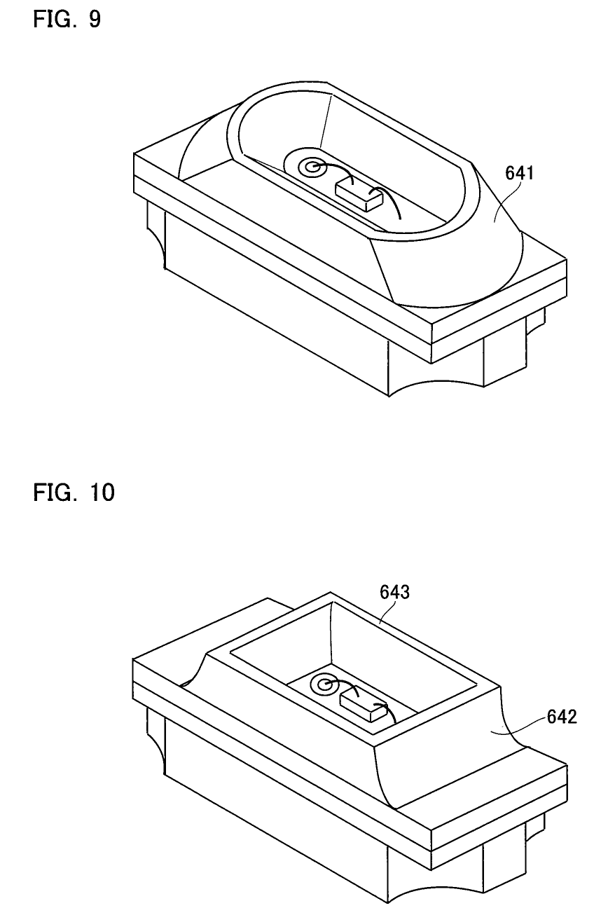

Further, the multilayer substrate 606 of the light emitting device 600 of the present embodiment has a fewer layers than the multilayer substrate 506 of the light emitting device 500 of First Embodiment discussed above does. This is discussed below with reference to FIGS. 7 and 8. Note that, since the multilayer substrate 606 is stacked on the metallic reflecting plate 502 to be combined, the metallic reflecting plate 502 is discussed as the first layer 621 in the following description.

FIG. 7 is a sectional view showing a detailed structure of the light emitting device 600.

FIG. 8 shows an etching pattern of the metallic reflecting plate 502 and respective layers of the multilayer substrate 606. In FIG. 8, (a) indicates the first layer 621, (b) indicates a second layer 622, (c) indicates a third layer 623, (d) indicates a fourth layer 624, (e) indicates a fifth layer 625, and (f) indicates a sixth layer 626.

The front layer 603 has a dual-layer structure in which the second layer 622 and the third layer 623 are stacked in this order from the mount surface.

In the second layer 622 (mount surface), the die-bonding-area/electrode section (first metal section) 607 and the island electrode (second metal section) 608 are formed as electrode terminals that supply driving current to the LED chip 501. The die-bonding-area/electrode section 607 and the island electrode 608 are both connected to the LED chip 501. The insulating ring 609 is formed in the shape of a ring so as to surround an outer edge of the island electrode 608. The insulating ring 609 electrically isolates the island electrode 608 from the die-bonding-area/electrode section 607.

On the mount surface of the present embodiment, the die-bonding-area/electrode section 607 is formed so as to surround the outer edge of the island electrode 608 via the insulating ring 609. This is a difference from First Embodiment. Specifically, the die-bonding-area/electrode section 607 serving as the mount-surface metallic reflecting film is also formed between the metallic reflecting film 602 and the insulating section 609, both of which are formed on the mount surface.

The die-bonding-area/electrode section 607, the island electrode 608, and the insulating ring 609 have the same structures as those of the die-bonding-area/electrode section 507, the island electrode 508, and the insulating section 509, respectively, except for the shapes discussed above.

The third layer 623 is provided to electrically connect the second layer 622 to the fourth layer 624, which will be discussed later. The third layer 623 has a function to improve the degree of adherability of the insulating section 609 at the time of forming the insulating section in the second layer 622.

To avoid contact with moisture and the air, it is preferable not to contain the light reflective filler, such as titanium dioxide, near the boundary surface that is to be bonded to other components via the third layer 623 serving as the bonding layer. Because the boundary surface separating from the bonding layer or from the other components is likely to hold moisture and/or the air, it is preferable not to bring the light reflective filler into contact. Further, resin that allows little gas such as the atmosphere to pass therethrough, such as epoxy resin, is commonly used as the resin of the insulating ring 609 to which titanium dioxide is to be added. It is thus especially preferable to provide the titanium dioxide-added resin layer 509c inside of the resin of the insulating ring 609.

In the third layer 623, a conductive section 631 and a conductive section 632 are formed to electrically connect respective electrodes formed on the mount surface to the rear electrode. Respective structures of the conductive sections 631 and 632 are basically the same as those of the conductive sections 531 and 532 of First Embodiment, respectively. Areas where the conductive section 631 and the conductive section 632 are to be formed are selected according to the shapes of the die-bonding-area/electrode section 607 and the island electrode 608.

The Following Describes the Middle Layer 604.

The middle layer 604 in the present embodiment differs from the multilayer substrate 506 of First Embodiment in that the middle layer 604 is constituted of the fourth layer 624 only, whereas the multilayer substrate 506 of First Embodiment includes the middle layer 504 having the triple-layer multilayer structure.

The fourth layer 624 is provided to electrically connect the third layer 623 to rear electrodes 518 and 519 formed on through holes 515 and 516 formed in the fifth layer 625 and the sixth layer 626, both of which will be described later.

The fourth layer 624 is formed in such a manner that a conductive section 633, which is electrically connected to the die-bonding-area/electrode section 607, and a conductive section 634, which is electrically connected to the island electrode 608, do not come into contact with each other.

The conductive section 633 is formed so as to cover the through hole 515 entirely so that copper does not leak when the through hole 515 is being plated with copper. In other words, the conductive section 633 has a function to cover the through hole 515. There is a possibility that a burr occurs during the dicing of the light emitting device 600, but the problem of short-circuit due to contact with the burr does not arise because the conductive section 633 and the metallic reflecting plate 502 have the same electric potential.

The conductive section 634 is formed so as to entirely cover an area of the third layer 623, in which area the conductive section 632 is formed. The conductive section 634 is smaller than the through hole 516 in width in the planar direction. To prevent damages due to a burr occurred at the time of dicing the light emitting device 600, the conductive section 634 is formed so as to leave a margin for dicing.

The Following Describes the Rear Layer 605.

The rear layer 605 has a dual-layer multilayer structure in which the fifth layer 625 and the sixth layer 626 are stacked in this order from the mount surface. The fifth layer 625 and the sixth layer 626 have the same structures as those of the seventh layer 527 and the eighth layer 528 of First Embodiment, respectively.

The rear layer 605, which is a laminate of the fifth layer 625 and the sixth layer 626, is bonded to the fourth layer 624 with an adhesive tape by pressing. At this time, the through hole 515 is formed in such a manner as to be covered by the conductive section 633 of the fourth layer 624.

On the other hand, the through hole 516 is formed in such a manner as to have the conductive section 634 of the fourth layer 624 inside of the through hole 516 and to be covered by the third layer 623. The conductive section 634 of the fourth layer 624 is made smaller than the through hole 516 in width in the planar direction so that it becomes possible to cover the through hole 516 with the third layer 623. Thus, geometrically, the fifth layer 625 and the sixth layer 626, which are combined to form a laminate, come into plane contact with the fourth layer 624 only via the conductive section 633. If pressure is applied, the fifth layer 625 and the sixth layer 626 are considered to tilt with a fulcrum at an uneven part of the conductive section 633, but properly adjusting the thickness of the conductive section 633 and the thickness of the adhesive tape enables the fifth layer 625 and the sixth layer 626, which are combined to form a laminate, to be bonded to the fourth layer 624 evenly without tilting. This makes it possible to prevent copper from leaking during a process of forming the copper plating 517, which process will be described later.

In this state, the copper plating 517 is formed on respective inner side surfaces of the through hole 515 and the through hole 516. The conductive section 633 of the fourth layer 624 is formed so as to cover the through hole 515. Thus, the copper plating 517 is also formed on the conductive section 633 of the fourth layer 624. Further, the third layer 623 and the conductive section 634 of the fourth layer 624 are formed so as to cover the through hole 516. Thus, the copper plating 517 is also formed on the third layer 623 and on the conductive section 634 of the fourth layer 624. The rear electrode 518 and the rear electrode 519 are formed accordingly to serve as external connection electrode terminals of the light emitting device 600.

As described above, the conductive section 634 of the fourth layer 624 is made smaller than the through hole 516, and the thickness of the conductive section 633 and the thickness of the adhesive tape are adjusted properly, whereby reduction in the number of laminate layers is achieved in the multilayer substrate 606. This makes it possible with the light emitting device 600 according to the present embodiment to reduce the size and production costs.

In the same manner as in First Embodiment, it is possible to determine the opening section of the metallic reflecting plate 502 and the shape of the outer side surface of the metallic reflecting plate 502 according to a shape and a design that are easy to etch. FIG. 9 shows a metallic reflecting plate 641 having a different outer shape. FIG. 10 shows a metallic reflecting plate 642 and an opening section 643 each having a different outer shape.

The rear electrode 518 and the rear electrode 519 are formed on the rear surface side opposite to the light outgoing surface to serve as the external connection electrode terminals of the light emitting device 600. The present embodiment, however, is not limited to this structure. It is also possible to provide the external connection electrode terminals on the light outgoing surface.

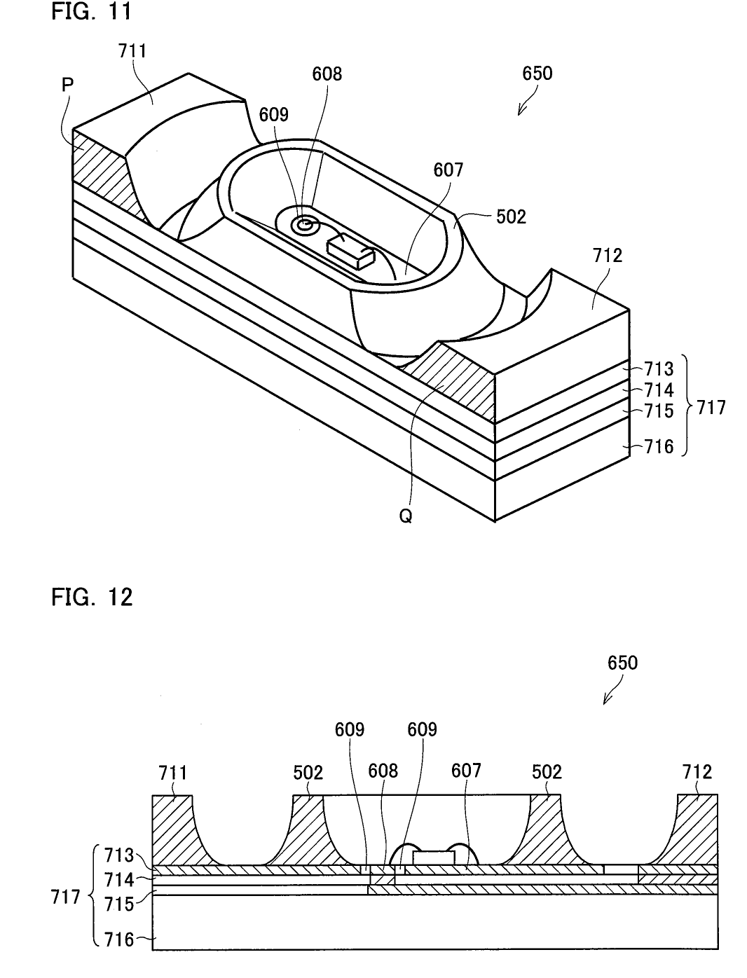

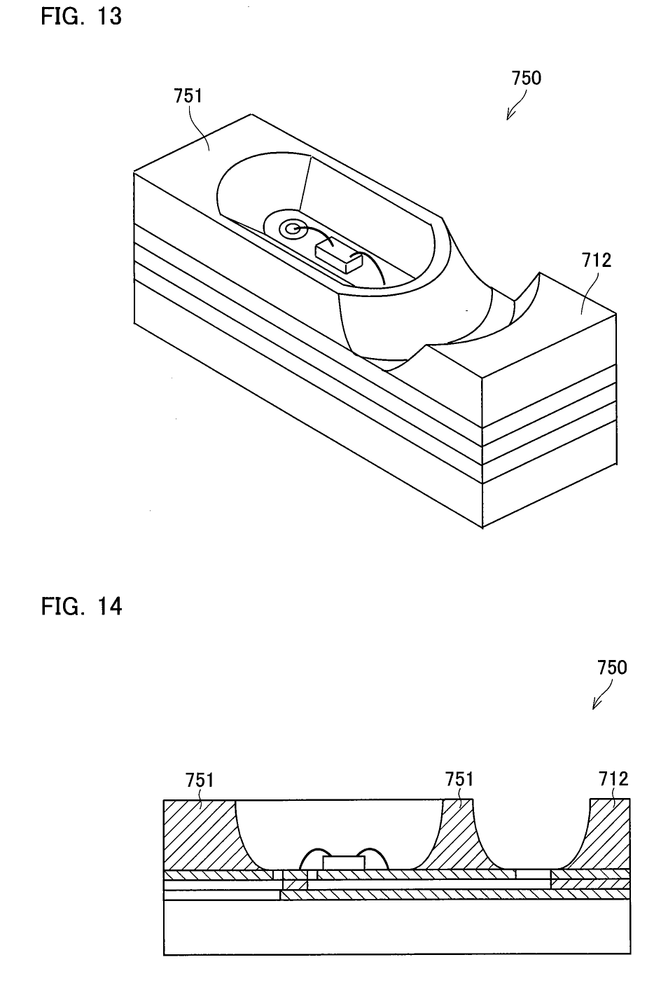

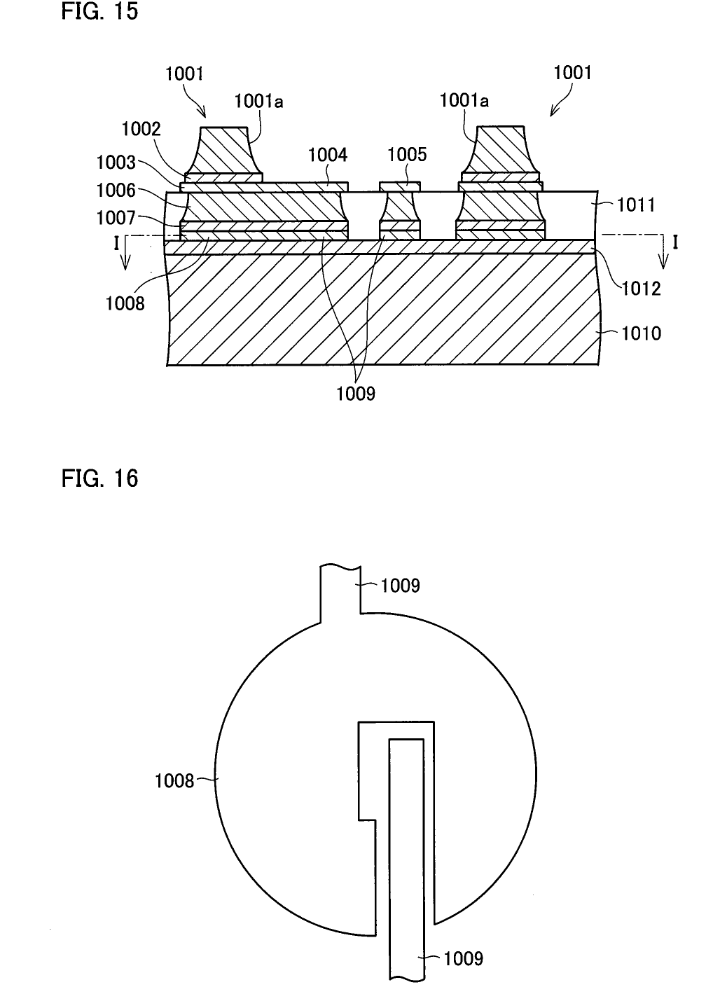

Specifically, as shown in FIGS. 11 and 12, an external junction electrode 711 and an external junction electrode 712 are formed so as to be combined with the metallic reflecting plate 502. This makes it possible to use areas P and Q as a solder junction surface so that solder wettability improves.

However, forming the external junction electrode 711 and the external junction electrode 712 causes the light emitting device to increase in package size. FIGS. 13 and 14 show a structure of a light emitting device having a reduced package size.

In the structure shown in FIGS. 13 and 14, a combined external junction electrode 751 constituted of a combination of the metallic reflecting plate 502 and the external junction electrode 711 is provided to reduce the package size of the light emitting device.

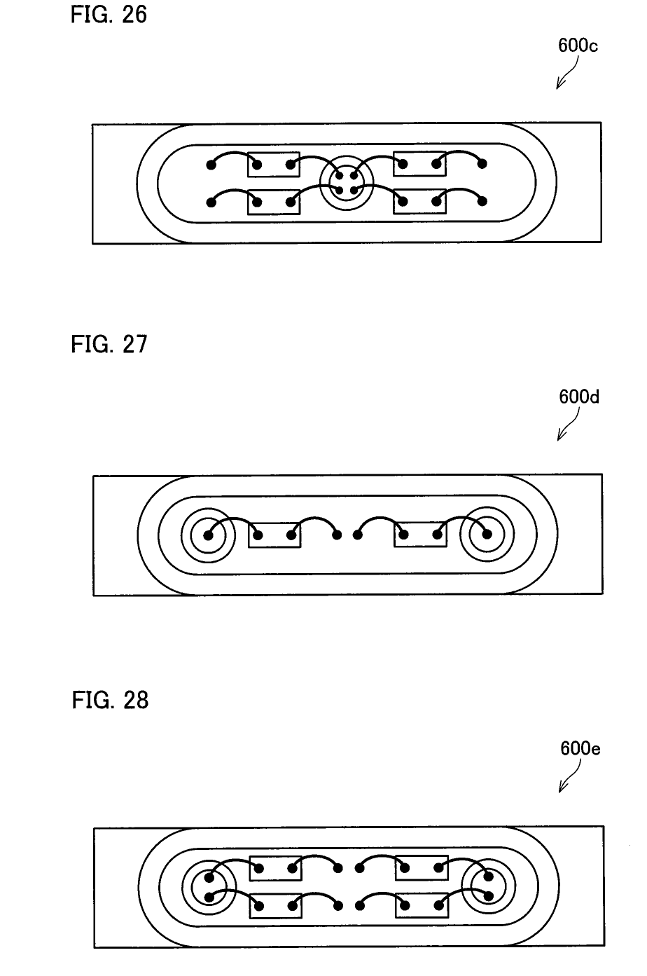

Although the foregoing discusses the structure having a single LED chip 501, the present embodiment is not limited to this structure. The present embodiment is also applicable to a structure having two or more LED chips, such as the light emitting device 600a shown in FIG. 24, the light emitting device 600b shown in FIG. 25, and the light emitting device 600c shown in FIG. 26.

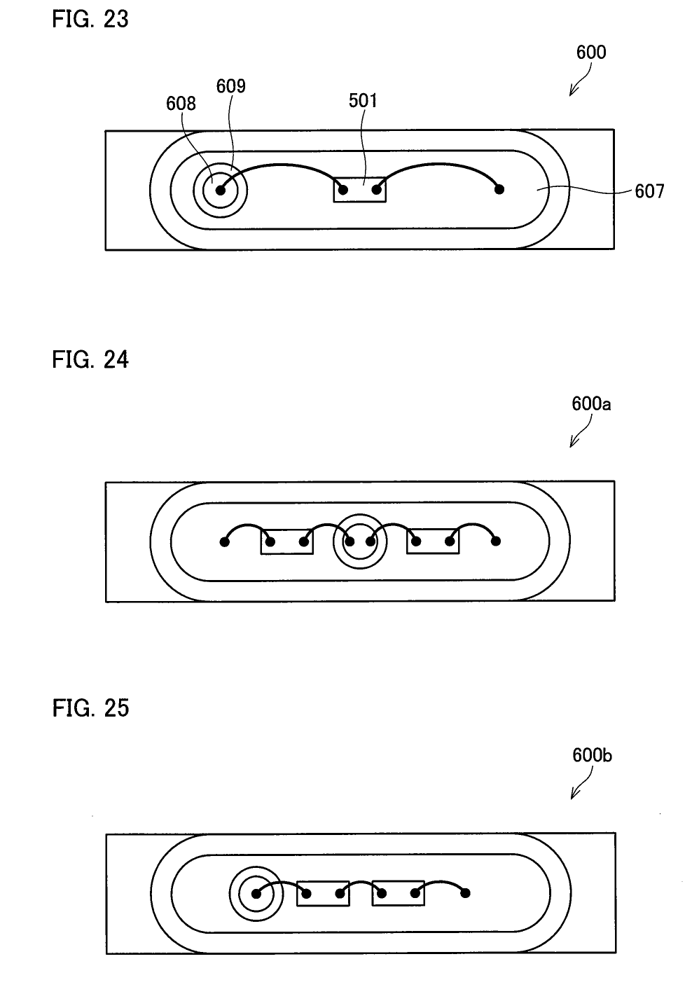

In the respective structures shown in FIGS. 23 to 26, the electric potential of the island electrode 608 differs from that of the other area surrounded by the metallic reflecting plate 502 and including the die-bonding-area/electrode section 607.

Plural LED chips are provided and mounted properly in a single light emitting device so that it becomes possible to improve the intensity of emitted light without an increase of the size of the element. The maximum number of LED chips to be provided is not limited to four, and it is possible in a structure with a larger element substrate to provide more LED chips.

### Third Embodiment

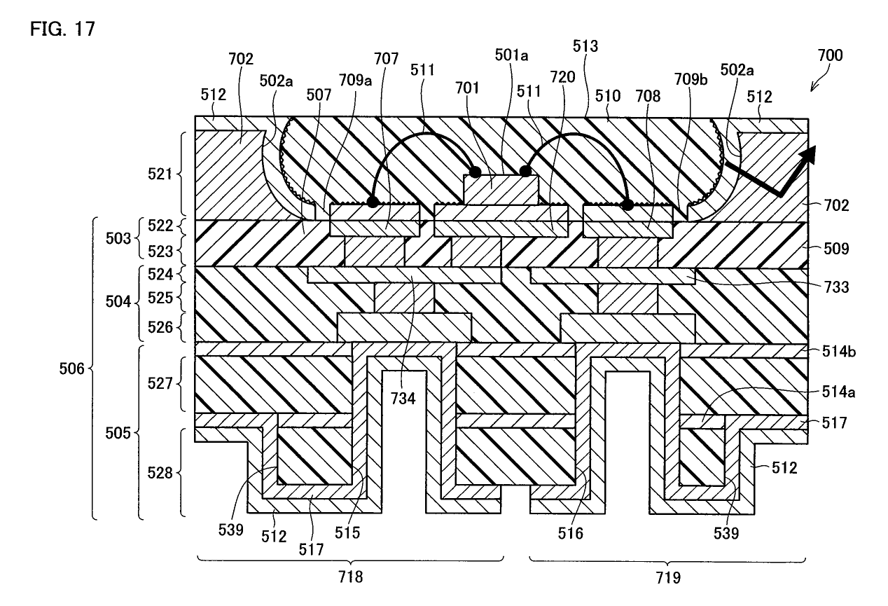

The following describes another embodiment of the present invention, with reference to FIGS. 17, 18, and 27-31. For the convenience of explanation, components having the same functions as those of the components shown in the figures of the foregoing embodiments are given the same reference numbers, and description thereof is omitted.

A light emitting device 700 according to the present embodiment includes a multilayer substrate same as the multilayer substrate 506 of the light emitting device 500 of First Embodiment discussed above.

As shown in FIG. 17, every electrode connected to an LED chip 701 and serving as an electrode terminal to supply driving current to the LED chip 701 is an island electrode. Specifically, a metallic reflecting plate 702 that reflects light from the LED chip 701 to guide the light to a light outgoing surface 513 provided in a direction in which light is emitted is electrically isolated from every electrode that supplies driving current to the LED chip 701. This is a difference from First Embodiment discussed above.

In the present embodiment, a cathode electrode of an LED chip 501 is connected to a first island electrode (first metal section) 707, and an anode electrode is connected to a second island electrode (second metal section) 708.

The first island electrode 707 is electrically isolated, by a first insulating section 709a formed in the shape of a ring so as to surround an outer edge of the first island electrode 707, from the other part of an area of a mount surface, which area is surrounded by the metallic reflecting plate 702.

In the same manner as the island electrode 508 of First Embodiment, the second island electrode 708 is electrically isolated, by a second insulating section 709b formed in the shape of a ring so as to surround the second island electrode 708, from the other part of the area.

Further, a mount-surface metallic reflecting film 720 is formed all over an area outside of the area where the first insulating section 709a and the second insulating section 709b are formed in the area surrounded by the metallic reflecting plate 702.

The first insulating section 709a and the second insulating section 709b are both made of RCC resin such as epoxy resin, in the same manner as the insulating section 509 of First Embodiment and the insulating ring 609 of Second Embodiment. The RCC resin contains a light reflective filler that reflects a visible light ray having a wavelength in the range of 400 nm to 850 nm. It is preferable that an optical reflectance of the RCC resin be 50% or above with respect to the wavelength in the range mentioned above. Aluminum oxide, silicon oxide, titanium dioxide, or the like, all of which have a high optical reflectance, is usable as the light reflective filler. The titanium dioxide is especially preferred because it has a high optical reflectance and is inexpensive.

However, the use of the titanium dioxide as the light reflective filler has a risk of oxidization of the metallic reflecting plate 702, a light-transmitting sealant 510, the first insulating section 709a, and/or the second insulating section 709b due to photocatalytic reaction in the presence of oxygen during light emission operation (oxygen comes from the atmosphere and/or moisture having passed through the sealing resin, having been absorbed by the peripheral components, and having stayed inside). On the other hand, the use of other reflective filler such as aluminum oxide and silicon oxide does not cause the photocatalysis. However, aluminum oxide and silicon oxide have hygroscopicity. Thus, there is a risk that the atmosphere and/or moisture absorbed in the process of sealing with the light-transmitting sealant 510 is vaporized by heat during light emission operation to cause the light-transmitting sealant 510 to peel off. It is preferable that the light-transmitting sealant 510 for sealing the LED chip 701 be excellent in light resistance and hermeticity. However, in general, resin having better light resistance transmits gas such as the atmosphere more easily, so that there is a possibility that the atmosphere/moisture reaches the mount surface.

Thus, when the light reflective filler is to be added only to the front layer near the mount surface of the LED chip 701, it is especially preferable to reduce the amount of light reflective filler added so that the optical reflectance improves while the amount of active oxygen to be oxidized is reduced.

To avoid contact with the air/moisture, it is preferable not to contain the light reflective filler, such as titanium dioxide, near a boundary surface that is to be bonded to other components via the third layer 623 serving as the bonding layer. Because the boundary surface separating from the bonding layer or from the other components is likely to hold moisture and/or the air, it is preferable not to bring the light reflective filler into contact. Further, resin that allows little gas such as the atmosphere to pass therethrough, such as epoxy resin, is commonly used as resin of the first insulating section 709a, to which titanium dioxide is to be added, and resin of the second insulating section 709b, to which titanium dioxide is to be added. It is thus especially preferable to provide a titanium dioxide-added resin layer 509c inside of the resin of the first insulating section 709a and the resin of the second insulating section 709b.

Accordingly, it is preferable that the first insulating section 709a and the second insulating section 709b each have a multilayer structure in which a light reflective filler-free resin layer containing no light reflective filler and a light reflective filler-added resin layer containing the light reflective filler are stacked in this order from a side via which light enters. RCC resin absorbs light. Thus, it is preferable to form the light reflective filler-free resin layer, which does not contain the light reflective filler, in the form of a layer as thin as possible and then to form the light reflective filler-added resin layer, which contains the light reflective filler, in a lower layer on the light reflective filler-free resin layer.

Processes of forming the first insulating section 709a and the second insulating section 709b are same as the process of forming the insulating section 509 of First Embodiment discussed above. Thus, description thereof is omitted here.

It is also possible with the use of titanium dioxide as the light reflective filler to improve the intensity of light emitted from a light outgoing surface while preventing the problem of oxidization of the metallic reflecting plate 702, the light-transmitting sealant 510, the first insulating section 709a, and/or the second insulating section 709b in the presence of oxygen due to photocatalytic reaction of the light reflective filler and the problem of peel-off of the light-transmitting sealant 510, compared with the case in which the light reflective filler is added all over the first insulating section 709a and the second insulating section 709b.

In other words, it is possible to reduce the amount of light absorbed by the first insulating section 709a and by the second insulating section 709b, and the amount of light passing through the substrate to be emitted to the outside via the rear surface. Thus, efficiency for light utilization and heat releasing property improve.

The resin containing the light reflective filler is used in the first insulating section 709a and in the second insulating section 709b so that the light reflective filler is allowed to reflect light that is emitted from the LED chip 701 and enters the first insulating section 709a and the second insulating section 709b and light that is emitted from a fluorescent material contained in the light-transmitting sealant 510, which seals the LED chip 701, and enters the first insulating section 709a and the second insulating section 709b. This makes it possible to reduce light that is partially absorbed and becomes attenuated when entering the first insulating section 709a and the second insulating section 709b and being reflected by a peripheral component, so that efficiency for light utilization and heat releasing property improve.

It is preferable that the RCC resin be formed by thermal processing in an atmosphere of inert gas. This makes it possible to prevent resin used in the first insulating section 709a and in the second insulating section 709b from deteriorating (changing to yellow), so that the foregoing effect is produced efficiently without absorption of light by the resin having deteriorated.

In the same manner as in First and Second Embodiments discussed above, the light emitting device 700 is arranged in such a manner that the metallic reflecting plate 702, which reflects light from the LED chip 701 to guide the light to the light outgoing surface 513 provided in the direction in which light is emitted, is provided in the direction in which the LED chip 701 emits light, and that the metallic reflecting plate 702 is provided so as to surround the LED chip 701 entirely. This allows the metallic reflecting plate 702 to reflect light emitted from the LED chip 701 to its surrounding area to efficiently guide the light to the light outgoing surface 513. It thus becomes possible to reduce leakage of light from a side surface of the element so that the intensity of light emitted from the light outgoing surface 513 improves.

Further, the mount-surface metallic reflecting film 720 is present between the first insulating section 709a and the metallic reflecting plate 702. The mount-surface metallic reflecting film 720 is also present between the second insulating section 709b and the metallic reflecting plate 702. Therefore, even if positional deviation occurs during a process of forming the metallic reflecting plate 702, the deviation is absorbed by the mount-surface metallic reflecting film 720. Thus, the positional deviation does not affect the shapes and areas of the first insulating section 709a and the second insulating section 709b. Accordingly, even if the first insulating section 709a and the second insulating section 709b on the mount surface of the substrate are reduced in area, the first island electrode 707 and the second island electrode 708 are sill kept isolated. With the foregoing structure, it is possible to further reduce respective areas of the first insulating section 709a and the second insulating section 709b, which are formed on the mount surface. Thus, it becomes possible to form the mount-surface metallic reflecting film 720, which surrounds the island electrode 707 and the second island electrode 708 via the insulating sections, so as to have a wider area. This makes it possible to more effectively prevent light from leaking from the second insulating section 709b, so that light traveling from the metallic reflecting plate 702 toward the substrate is reflected by the mount-surface metallic reflecting film toward the light outgoing surface 513 more efficiently. Thus, efficiency for light utilization and heat releasing property further improve.

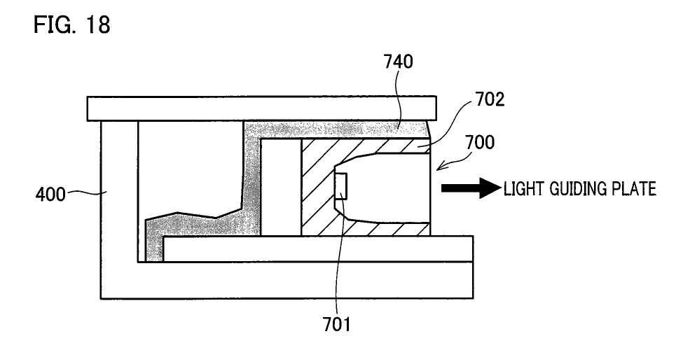

The metallic reflecting plate 702 according to the present embodiment is electrically isolated from both of the first island electrode 707 and the second island electrode 708, as described above. Thus, as shown in FIG. 18, the metallic reflecting plate 702 does not come to have electric potential at the time when the light emitting device 700 is mounted on a housing 400, which is made of metal such as aluminum, of an electronic device such as mobile phones. Therefore, it is possible to mount the light emitting device 700 with the metallic reflecting plate 702 being in contact with the housing 400, without using intervening resin or the like having low heat releasing property. This allows heat generated in the metallic reflecting plate 702 to escape to the outside of the light emitting device 700 efficiently.

As shown in FIG. 18, the light emitting device 700 according to the present embodiment is arranged in such a manner that a heat radiating sheet 740 for allowing heat generated in the metallic reflecting plate 702 to escape to the outside is formed on at least a part of an outer surface of the metallic reflecting plate 702 and on an outer surface of the element, including a bottom surface of the multilayer substrate 506.

The foregoing allows the heat generated in the metallic reflecting plate 702 to escape to the outside via the heat radiating sheet 740 more efficiently.

It is preferable to use a conductive material with excellent heat releasing property as the heat radiating sheet 740. As described above, the metallic reflecting plate 702 according to the present embodiment is isolated from the other components, so that it does not come to have electric potential. Therefore, the heat generated in the metallic reflecting plate 702 is allowed to efficiently escape to the outside via the heat radiating sheet, which is made of the conductive material having excellent heat releasing property, without causing a problem of short-circuit or the like. Use of a graphite-series material, which is especially excellent in heat releasing property, as the conductive material is preferred.

Further, the mount-surface metallic reflecting film 720 is formed in an area of the mount surface, which area is outside of the first insulating section 709a and the second insulating section 709b. This allows much of light emitted from the LED chip 701 and traveling toward the substrate to be reflected by the mount-surface metallic reflecting film 720 to be guided toward the light outgoing surface 513 provided in the direction in which light is emitted. Thus, it becomes possible to reduce the amount of light absorbed by the substrate and the amount of light passing through the substrate to escape to the outside of the light emitting device 700 via the rear surface, so that the intensity of the light emitted from the light outgoing surface improves.

In the light emitting device 700, a rear electrode (first rear electrode) 718 and a rear electrode (second rear electrode) 719 are formed on a rear surface of the multilayer substrate 506, which rear surface is opposite to the mount surface. The rear electrode 718 and the rear electrode 719 are to be connected to the first island electrode 707 and the second island electrode 708, respectively, and serve as external connection electrode terminals.

The rear electrodes 718 and 719 are provided on the rear surface of the mounted substrate to serve as the external connection electrode terminals of the light emitting device 700. This makes it possible to reduce the amount of light that passes through the mounted substrate to leak from the light emitting device 700 to the outside via the rear surface.

It should be noted that the present embodiment is not limited to the foregoing arrangement. It is also possible to provide the external connection electrode terminals on the light outgoing surface.

Further, as shown in FIG. 17, the rear electrode 718 and the rear electrode 719 are formed so as to respectively and entirely cover areas that correspond, in the laminate direction, to areas where the first insulating section 709a and the second insulating section 709b are formed.

Thus, light that is emitted from the LED chip 701 and travels from the mount surface toward an inner part of the substrate is effectively prevented from passing through the multilayer substrate 506 via the first insulating section 709a and the second insulating section 709b to leak to the outside of the light emitting device via the rear surface. This makes it possible to improve the intensity of light emitted from the light outgoing surface.

Further, in the same manner as in First Embodiment, the rear electrode 718 and the rear electrode 719 are electrically connected to the first island electrode 707 and the second island electrode 708 via the conductive section 734 formed in the fourth layer 524 and the conductive section 733 formed in the fourth layer 524, respectively. In the present embodiment, the conductive section 734 and the conductive section 733 are formed so as to respectively and entirely cover areas that correspond, in the laminate direction, to areas where the first insulating section 709a and the second insulating section 709b are formed.

The first insulating section 709a and the second insulating section 709b are formed so as to be respectively covered by the conductive section 734 and the conductive section 733, which are formed closer to the substrate mount surface than to the rear electrode 718 and the rear electrode 719. This makes it possible to more effectively reduce the amount of light that leaks to the outside of the element through the first insulating section 709a and the second insulating section 709b via the rear surface.

In the same manner as in the embodiments discussed above, an upper end section, in the direction in which the LED chip 701 emits light, of a space surrounded by the mount surface and the metallic reflecting plate 702 in the light emitting device 700 is opened to form the light outgoing surface 513. The space is filled with the light-transmitting sealant 510. A middle part of the space between the light outgoing surface 513 and the mount surface, which is the bottom surface, has a widest cross section in a planar direction. The cross section is wider than the greatest width of the light outgoing surface 513 in the planar direction. That opening is narrowed from the middle part to the light outgoing surface 513.

Silicon or the like having weaker adhesion property than epoxy or the like is used as the sealing resin of the light-transmitting sealant 510. Therefore, the metallic reflecting plate 702 is formed in the manner as described above to narrow the opening forming the light outgoing surface 513, whereby adhesion of the light-transmitting sealant 510 with respect to the inner side surface of the metallic reflecting plate 702 improves so that the light-transmitting sealant 510 is prevented from peeling off. Thus, the silver-plated inner side surface of the metallic reflecting plate 702 is stably protected by the light-transmitting sealant 510.

It is preferable to process at least the inner side surface of the metallic reflecting plate 702, which surface is in contact with the light-transmitting sealant 510, so that the inner side surface becomes scabrous, as shown in FIG. 17. This increases a contact area that is in contact with the light-transmitting sealant 510, whereby adhesion of the light-transmitting sealant 510 with respect to the inner side surface of the metallic reflecting plate 702 improves so that the light-transmitting sealant 510 is prevented from peeling off. Thus, the silver-plated inner side surface of the metallic reflecting plate 702 is stably protected by the light-transmitting sealant 510.

It is preferable to use copper, silver, gold, or nickel, each having excellent reflectivity among the metals, as materials of the first island electrode 707, the second island electrode 708, the metallic reflecting plate 702, and the mount-surface metallic reflecting film 720, all of which constitute the light emitting device 700 according to the present embodiment. Use of copper, silver, gold, or nickel allows light emitted from the LED chip 701 to be guided to the light outgoing surface 513 efficiently.

Although the foregoing discusses the structure having a single island electrode 608, the present embodiment is not limited to the structure. It is also possible to provide plural island electrodes in the same manner as, for example, the light emitting device 600d shown in FIG. 27 or the light emitting device 600e shown in FIG. 28.

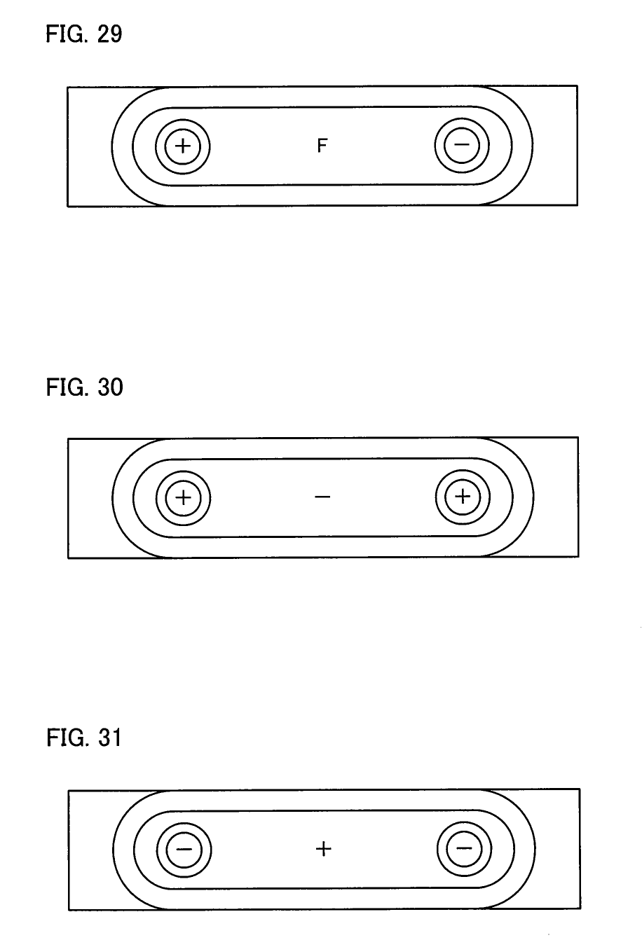

In a case in which two LED chips 501 are connected serially in the structure shown in FIG. 17, and in a case in which sets of two LED chips connected parallel are connected serially in the structure shown in FIG. 18, two island electrodes are electrically connected to different rear electrodes to have different electric potentials in such a manner that one of the two island electrodes becomes an anode and the other one of the two island electrodes becomes a cathode as shown in FIG. 29. In a case in which two chips are connected serially in the structure shown in FIG. 27 and four LED chips 501 are connected parallel as shown in FIG. 28, those two island electrodes have a same electric potential as shown in either FIG. 30 or FIG. 31. In this case, those two island electrodes include conductive sections in the layers of the multilayer substrate so that each of the two island electrodes is electrically connected to one of the rear electrodes (not illustrated).

In FIGS. 29 to 31, “+” and “−” indicate how the anode (+) and the cathode (−) are specified on the island electrode and on the die-bonding-area/electrode section, and F indicates that the electric potential is not specified but set to floating electric potential. This indication is also used in the embodiments discussed below.

### Fourth Embodiment

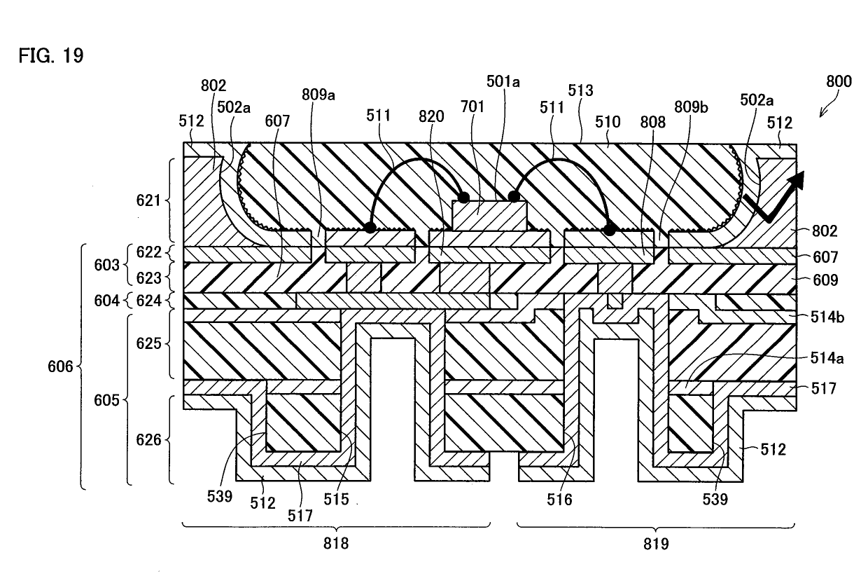

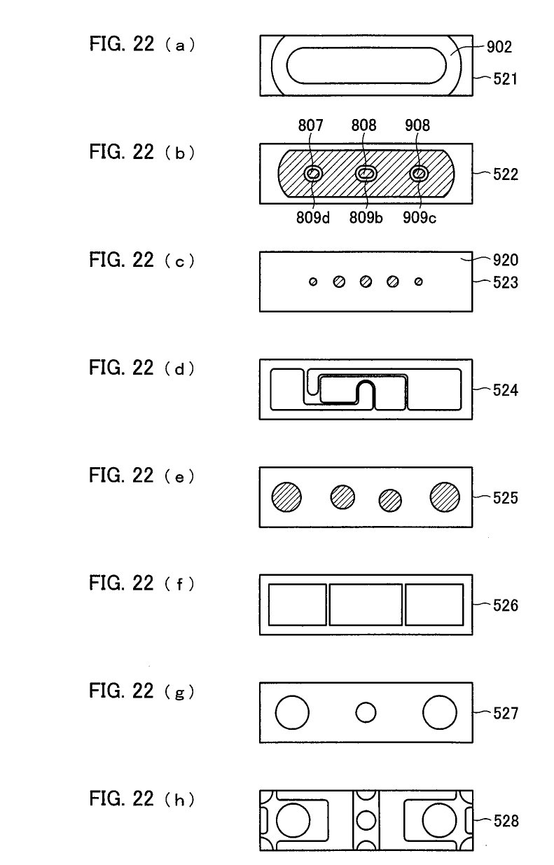

The following describes another embodiment of the present invention, with reference to FIGS. 19, 20, 22, 29, and 32-34. For the convenience of explanation, components having the same functions as those of the components shown in the figures of the foregoing embodiments are given the same reference numbers, and description thereof is omitted.

A light emitting device 800 according to the present embodiment includes a multilayer substrate same as the multilayer substrate 606 of the light emitting device 600 of Second Embodiment discussed above.

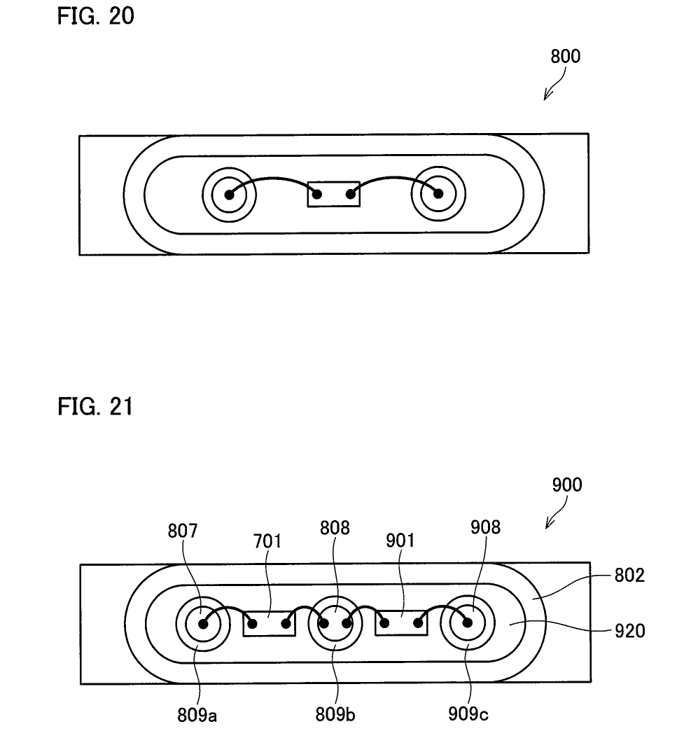

As shown in FIGS. 19 and 20, every electrode terminal connected to an LED chip 701 to serve as an electrode terminal supplying driving current to the LED chip 701 in the light emitting device 800 according to the present embodiment is an island electrode, in the same manner as the light emitting device 700 of Third Embodiment discussed above. A metallic reflecting plate 802, which reflects light from the LED chip 701 to guide the light to a light outgoing surface 513 provided in a direction in which light is emitted, is electrically isolated from every electrode that supplies driving current to the LED chip 701. This is a difference from Second Embodiment discussed above.

In the present embodiment, a cathode electrode of the LED chip 701 is connected to a first island electrode (first metal section) 807, and an anode electrode is connected to a second island electrode (second metal section) 808.

The first island electrode 807 is electrically isolated, by a first insulating section 809a formed in the shape of a ring so as to surround an outer edge of the first island electrode 807, from the other part of an area of a mount surface, which area is surrounded by the metallic reflecting plate 802.

The second island electrode 808 is electrically isolated, by a second insulating section 809b formed in the shape of a ring so as to surround the second island electrode 808, from the other part of the area, in the same manner as the island electrode 608 of Second Embodiment.

Further, a mount surface metallic reflecting film 820 is formed all over the area outside of the first insulating section 809a and the second insulating section 809b.

The first insulating section 809a and the second insulating section 809b are both made of RCC resin such as epoxy resin, in the same manner as the insulating section 509 of First Embodiment, the insulating section 609 of Second Embodiment, and the first insulating section 709a and the second insulating section 709b of Third Embodiment. The RCC resin contains a light reflective filler that reflects a visible light ray having a wavelength in the range of 400 nm to 850 nm. It is preferable that an optical reflectance of the RCC resin be 50% or above with respect to the wavelength in the range mentioned above. Aluminum oxide, silicon oxide, titanium dioxide, or the like, all of which have a high optical reflectance, is usable as the light reflective filler. The titanium dioxide is especially preferred because it has a high optical reflectance and is inexpensive.

However, the use of the titanium dioxide as the light reflective filler has a risk of oxidization of the metallic reflecting plate 802, a light-transmitting sealant 510, the first insulating section 809a, and/or the second insulating section 809b due to photocatalytic reaction in the presence of oxygen during light emission operation (oxygen comes from the atmosphere and/or moisture having passed through the sealing resin, having been absorbed by the peripheral components, and having stayed inside). On the other hand, the use of other reflective filler such as aluminum oxide and silicon oxide does not cause the photocatalysis. However, aluminum oxide and silicon oxide have hygroscopicity. Thus, there is a risk that the atmosphere and/or moisture absorbed in the process of sealing with the light-transmitting sealant 510 is vaporized by heat during light emission operation to cause the light-transmitting sealant 510 to peel off. It is preferable that the light-transmitting sealant 510 for sealing the LED chip 701 be excellent in light resistance and hermeticity. However, in general, resin having better light resistance transmits gas such as the atmosphere more easily, so that there is a possibility that the atmosphere/moisture reaches the mount surface.

Thus, when the light reflective filler is to be added only to the front layer near the mount surface of the LED chip 701, it is especially preferable to reduce the amount of light reflective filler added so that the optical reflectance improves while the amount of active oxygen to be oxidized is reduced.

To avoid contact with the air/moisture, it is preferable not to contain the light reflective filler, such as titanium dioxide, near a boundary surface that is to be bonded to other components via the third layer 623 serving as the bonding layer. Because the boundary surface separating from the bonding layer or from the other components is likely to hold moisture and/or the air, it is preferable not to bring the light reflective filler into contact. Further, resin that allows little gas such as the atmosphere to pass therethrough, such as epoxy resin, is commonly used as resin of the first insulating section 809a, to which titanium dioxide is to be added, and resin of the second insulating section 809b, to which titanium dioxide is to be added. It is thus especially preferable to provide a titanium dioxide-added resin layer 509c inside of the resin of the first insulating section 809a and the resin of the second insulating section 809b.

Accordingly, it is preferable that the first insulating section 809a and the second insulating section 809b each have a multilayer structure in which a light reflective filler-free resin layer containing no light reflective filler and a light reflective filler-added resin layer containing the light reflective filler are stacked in this order from a side via which light enters. RCC resin absorbs light. Thus, it is preferable to form the light reflective filler-free resin layer, which does not contain the light reflective filler, in the form of a layer as thin as possible and then to form the light reflective filler-added resin layer, which contains the light reflective filler, in a lower layer on the light reflective filler-free resin layer.

Processes of forming the first insulating section 809a and the second insulating section 809b are same as the process of forming the insulating section 509 of First Embodiment discussed above. Thus, description thereof is omitted here.

Use of titanium dioxide as the light reflective filler causes the conductive layer to oxidize by photocatalytic reaction in the presence of oxygen. Therefore, it is preferable in this case to form the light reflective filler as far as possible from the conductive layer. Further, to keep the light reflective filler away from the atmosphere containing oxygen, it is preferable not to add the light reflective filler to a front surface of the mount surface.

Accordingly, it is preferable that the first insulating section 809a and the second insulating section 809b each have a multilayer structure in which a light reflective filler-free resin layer containing no light reflective filler and a light reflective filler-added resin layer containing the light reflective filler are stacked in this order from a side via which light enters. RCC resin absorbs light. Thus, it is preferable to form the light reflective filler-free resin layer, which does not contain the light reflective filler, in the form of a layer as thin as possible and then to form the light reflective filler-added resin layer, which contains the light reflective filler, in a lower layer on the light reflective filler-free resin layer.

Processes of forming the first insulating section 809a and the second insulating section 809b are same as the process of forming the insulating section 509 of First Embodiment. Thus, description thereof is omitted here.

It is also possible with the use of titanium dioxide as the light reflective filler to improve the intensity of light emitted from a light outgoing surface while preventing the problem of oxidization of the metallic reflecting plate 802, the light-transmitting sealant 510, the first insulating section 809a, and/or the second insulating section 809b in the presence of oxygen due to photocatalytic reaction of the light reflective filler and the problem of peel-off of the light-transmitting sealant 510, compared with the case in which the light reflective filler is added all over the first insulating section 809a and the second insulating section 809b.

In other words, it is possible to reduce the amount of light absorbed by the first insulating section 809a and by the second insulating section 809b, and the amount of light passing through the substrate to be emitted to the outside via the rear surface. Thus, efficiency for light utilization and heat releasing property improve.

The resin containing the light reflective filler is used in the first insulating section 809a and in the second insulating section 809b so that the light reflective filler is allowed to reflect light that is emitted from the LED chip 701 and enters the first insulating section 809a and the second insulating section 809b and light that is emitted from a fluorescent material contained in the light-transmitting sealant 510, which seals the LED chip 701, and enters the first insulating section 809a and the second insulating section 809b. This makes it possible to reduce light that is partially absorbed and becomes attenuated when entering the first insulating section 809a and the second insulating section 809b and being reflected by a peripheral component, so that efficiency for light utilization and heat releasing property improve.

It is preferable that the RCC resin be formed by thermal processing in an atmosphere of inert gas. This makes it possible to prevent resin used in the first insulating section 809a and in the second insulating section 809b from deteriorating (changing to yellow), so that the foregoing effect is produced efficiently without absorption of light by the resin having deteriorated.

In the same manner as in First to Third Embodiments discussed above, the light emitting device 800 is arranged in such a manner that the metallic reflecting plate 802, which reflects light from the LED chip 701 to guide the light to the light outgoing surface 513 provided in the direction in which light is emitted, is provided in the direction in which the LED chip 701 emits light, and that the metallic reflecting plate 802 is provided so as to surround the LED chip 701 entirely. This allows the metallic reflecting plate 802 to reflect light emitted from the LED chip 701 to its surrounding area to efficiently guide the light to the light outgoing surface 513. It thus becomes possible to reduce leakage of light from a side surface of the element so that the intensity of light emitted from the light outgoing surface 513 improves.

As shown in FIG. 19, the light emitting device 800 according to the present embodiment is arranged in such a manner that the metallic reflecting plate 802 and the mount-surface metallic reflecting film 820 are combined together.

This makes it possible to form the mount-surface metallic reflecting film 820 over a wide area of the mount surface. Increasing this metal-formed area in the whole element makes it possible to realize a light emitting device having excellent heat releasing property. It also becomes possible to convey heat generated at the time of emission of light from the LED chip 701 to a front surface of the multilayer substrate 606, with which the mount-surface metallic reflecting film 820 is combined, and release the heat to a rear surface effectively. The foregoing makes it possible to reduce deterioration due to heat and therefore to realize a light emitting device with long-term reliability.

In the present embodiment, the metallic reflecting plate 802 is electrically isolated from both the first island electrode 807 and the second island electrode 808, as described above. Thus, as shown in FIG. 29, the metallic reflecting plate 802 does not come to have electric potential at the time of mounting the light emitting device 800 on a housing 400, which is made of metal such as aluminum, of an electronic device such as a mobile phone. Therefore, it is possible to mount the light emitting device 800 with the metallic reflecting plate 802 being in contact with the housing 400, without using intervening resin or the like having low heat releasing property. This allows heat generated in the metallic reflecting plate 802 to escape to the outside of the light emitting device 800 efficiently.

In the same manner as the light emitting device 700 of Third Embodiment, the light emitting device 800 according to the present embodiment is arranged in such a manner that a heat radiating sheet 740 for allowing heat generated in the metallic reflecting plate 802 to escape to the outside is formed on at least a part of an outer surface of the metallic reflecting plate 802 and on an outer surface of the element, including a bottom surface of the multilayer substrate 606.

The foregoing allows the heat generated in the metallic reflecting plate 802 to escape to the outside via the heat radiating sheet 740 more efficiently.

It is preferable to use a conductive material with excellent heat releasing property as the heat radiating sheet 740. As described above, the metallic reflecting plate 802 according to the present embodiment is isolated from the other components, so that it does not come to have electric potential. Therefore, the heat generated in the metallic reflecting plate 802 is allowed to efficiently escape to the outside via the heat radiating sheet, which is made of the conductive material having excellent heat releasing property, without causing a problem of short-circuit or the like. Use of a graphite-series material, which is especially excellent in heat releasing property, as the conductive material is preferred.

Further, this conductive heat radiating sheet is grounded so as to be isolated from the rear electrode on the housing. Thus, electric potential of the mount-surface metallic reflecting film having a metallic reflecting plate and an LED chip that is electrically and thermally connected to the metallic reflecting plate does not float. This prevents an unnecessary electrical surge to flow into the LED chip to damage the light emitting device or cause the light emitting device to operate improperly.

Differing from Third Embodiment discussed above, the first insulating section 809a and the second insulating section 809b on the mount surface are respectively formed in the shape of a ring in the present embodiment. Thus, it becomes possible with a smaller area to isolate the respective electrodes from the other part.

Accordingly, it is possible to form the mount-surface metallic reflecting film 820 as shown in FIGS. 19 and 20. Specifically, the mount-surface metallic reflecting film 820 is widely and entirely formed over the area of the mount surface, which area is surrounded by the metallic reflecting plate 802. The mount-surface metallic reflecting film 820 is formed so as to surround the first island electrode 807 and the second island electrode 808 via the insulating sections 809a and 809b. This allows much of light emitted from the LED chip 701 and traveling toward the substrate to be reflected by the mount-surface metallic reflecting film 820 to be guided toward the light outgoing surface 513 provided in the direction in which light is emitted. Thus, it becomes possible to more effectively reduce the amount of light absorbed by the multilayer substrate 606 and the amount of light passing through the multilayer substrate 607 to escape to the outside of the light emitting device 800 via the rear surface. Therefore, the intensity of light emitted from the light outgoing surface improves, compared with the structure of Third Embodiment.

In the light emitting device 800, a rear electrode (first rear electrode) 818 and a rear electrode (second rear electrode) 819 are formed on a rear surface of the multilayer substrate 606, which rear surface is opposite to the mount surface. The rear electrode 818 and a rear electrode 819 are to be connected to the first island electrode 807 and the second island electrode 808, respectively, and serve as external connection electrode terminals.

The rear electrodes 818 and 819 are provided on the rear surface of the mounted substrate 606 to serve as the external connection electrode terminals of the light emitting device 800. This makes it possible to reduce the amount of light that passes through the mounted substrate 606 to leak from the light emitting device 800 to the outside via the rear surface.

It should be noted that the present embodiment is not limited to the foregoing arrangement. It is also possible to provide the external connection electrode terminals on the light outgoing surface.

Further, as shown in FIG. 19, the rear electrode 818 and the rear electrode 819 are formed so as to respectively and entirely cover areas that correspond, in the laminate direction, to areas where the first insulating section 809a and the second insulating section 809b are formed.

Thus, in the same manner as the light emitting devices according to the embodiments discussed above, light that is emitted from the LED chip 701 and travels from the mount surface toward an inner part of the substrate is effectively prevented from passing through the multilayer substrate 606 via the first insulating section 809a and the second insulating section 809b to leak to the outside of the light emitting device 800 via the rear surface. This makes it possible to improve the intensity of light emitted from the light outgoing surface.

It is preferable to use copper, silver, gold, or nickel, each having excellent reflectivity among the metals, as materials of the first island electrode 807, the second island electrode 808, the metallic reflecting plate 802, and the mount-surface metallic reflecting film 820, all of which constitute the light emitting device 800 of the present embodiment. Use of copper, silver, gold, or nickel allows light emitted from the LED chip 701 to be guided to the light outgoing surface 513 efficiently.

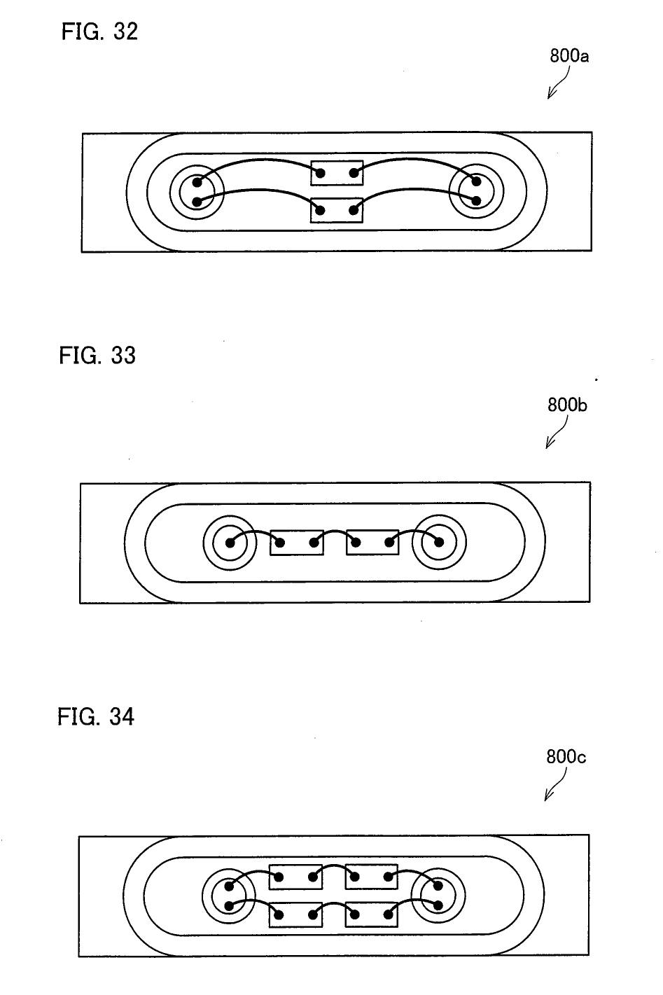

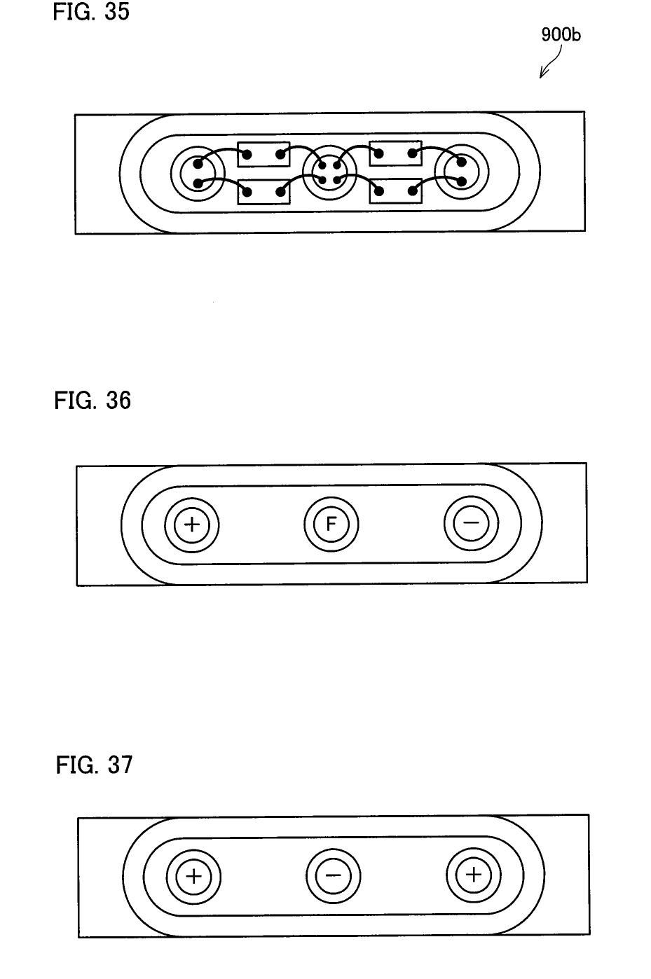

Although the foregoing discusses the structure having a single LED chip 701, the present embodiment is not limited to the structure. It is also possible to provide two or more LED chips in the same manner as, for example, the light emitting device 800a shown in FIG. 32, the light emitting device 800b shown in FIG. 33, or the light emitting device 800c shown in FIG. 34.

In a case in which two LED chips are connected parallel/serially as shown in FIGS. 32 and 33, and in a case in which sets of two LED chips connected parallel are connected serially as shown in FIG. 34, two island electrodes are arranged to have different electric potentials in such a manner that one of the two island electrodes becomes an anode and the other one of the two island electrodes becomes a cathode as shown in FIG. 29.

Plural LED chips are provided and mounted properly in a single light emitting device so that it becomes possible to improve the intensity of emitted light without an increase of the size of the element. The maximum number of LED chips to be provided is not limited to four, and it is possible in a structure with a larger element substrate to provide more LED chips.

### Fifth Embodiment

The following describes another embodiment of the present invention, with reference to FIGS. 21 and 35-37. For the convenience of explanation, components having the same functions as those of the components shown in the figures of the foregoing embodiments are given the same reference numbers, and description thereof is omitted.

Although the respective embodiments above discussed a light emitting device having a single LED chip, the light emitting device of the present invention is not limited to this arrangement and may have plural LED chips.

Thus, the following describes a case in which the structure discussed in Fourth Embodiment includes plural LED chips, with reference to FIG. 21.

As shown in FIG. 21, a light emitting device 900 according to the present embodiment includes an LED chip 701 and an LED chip (second LED chip) 901.

In the same manner as the light emitting device 800, a cathode electrode of the LED chip 701 is connected to a first island electrode (first metal section) 807, and an anode electrode is connected to a second island electrode (second metal section) 808.

In the present embodiment, the second island electrode 808, which serves as an electrode terminal supplying driving current to the LED chip 701, also has a function to serve as a power terminal supplying driving current to the LED chip 901. Specifically, the second island electrode 808 is also connected to an anode electrode of the LED chip 901. Further, the light emitting device 900 includes a third island electrode 908 connected to a cathode electrode of the LED chip 901 and serving as a power terminal that is electrically connected to the first island electrode 807 in a multilayer substrate via a conductive section. A metallic reflecting plate 802 is electrically isolated from all of the first to third island electrodes.

In the same manner as the light emitting device 800 of Fourth Embodiment discussed above, the first island electrode 807 is electrically isolated, by a first insulating section 809a formed in the shape of a ring so as to surround an outer edge of the first island electrode 807, from the other part of an area of a mount surface, which area is surrounded by the metallic reflecting plate 802. Further, the second island electrode 808 is electrically isolated, by a second insulating section 809b formed in the shape of a ring so as to surround an outer edge of the second island electrode 808, from the other part of the area, in the same manner as the island electrodes 608 and 808 of Second and Fourth Embodiments.

Further, in the present embodiment, the third island electrode (third electrode section) 908 is also electrically isolated, by a third insulating section 909c formed in the shape of a ring so as to surround an outer edge of the third island electrode, from the other part of the area.

In the light emitting device 900 of the present embodiment, two LED chips (LED chips 701 and 901) are provided in a single circuit system. This makes it possible to obtain a double intensity of emitted light without an increase of the size of the element.

In the present embodiment, the first to third insulating sections are formed on the mount surface in the shape of a ring, in the same manner as in Fourth Embodiment discussed above. Thus, it becomes possible with a smaller area to isolate the respective electrodes from the other part.

Thus, as shown in FIG. 21, it is possible to widely and entirely form a mount-surface metallic reflecting film 920 within an area of the mount surface, which area is surrounded by the metallic reflecting plate 802, in such a manner as to surround the first to third island electrodes 807-809 via the first to third insulating sections. This allows much of light emitted from the LED chips 701 and 901 and traveling toward the substrate to be reflected by the mount-surface metallic reflecting film 920 to be guided toward the light outgoing surface 513. Thus, it becomes possible to reduce the amount of light absorbed by a multilayer substrate 606 and the amount of light passing through a multilayer substrate 607 to escape to the outside of the light emitting device 900 via a rear surface.

In the same manner as the insulating section 509 of First Embodiment, the insulating section 609 of Second Embodiment, and the first insulating section 709a and the second insulating section 709b of Third Embodiment, the first insulating section 809a, the second insulating section 809b, and the third insulating section 909c are each made of RCC resin such as epoxy resin. The epoxy resin contains a light reflective filler that reflects a visible light ray having a wavelength in the range of 400 nm to 850 nm. It is preferable that an optical reflectance of the RCC resin be 50% or above with respect to the wavelength in the range mentioned above. Aluminum oxide, silicon oxide, titanium dioxide, or the like, all of which have a high optical reflectance, is usable as the light reflective filler. The titanium dioxide is especially preferred because it has a high optical reflectance and is inexpensive.

However, the use of the titanium dioxide as the light reflective filler has a risk of oxidization of a metallic reflecting plate 702, a light-transmitting sealant 510, the first insulating section 809a, the second insulating section 809b, and/or the third insulating section 909c, due to photocatalytic reaction in the presence of oxygen during light emission operation (oxygen comes from the atmosphere and/or moisture having passed through the sealing resin, having been absorbed by the peripheral components, and having stayed inside). On the other hand, the use of other reflective filler such as aluminum oxide and silicon oxide does not cause the photocatalysis. However, aluminum oxide and silicon oxide have hygroscopicity. Thus, there is a risk that the atmosphere and/or moisture absorbed in the process of sealing with the light-transmitting sealant 510 is vaporized by heat during light emission operation to cause the light-transmitting sealant 510 to peel off. It is preferable that the light-transmitting sealant 510 for sealing the LED chips 701 and 901 be excellent in light resistance and hermeticity. However, in general, resin having better light resistance transmits gas such as the atmosphere more easily, so that there is a possibility that the atmosphere/moisture reaches the mount surface.

Thus, when the light reflective filler is to be added only to the front layer near the mount surface of the LED chips 701 and 901, it is especially preferable to reduce the amount of light reflective filler added so that the optical reflectance improves while the amount of active oxygen to be oxidized is reduced.

To avoid contact with moisture and the air, it is preferable not to contain the light reflective filler, such as titanium dioxide, near the boundary surface that is to be bonded to other components via a third layer 623 serving as a bonding layer. Because the boundary surface separating from the bonding layer or from the other components is likely to hold moisture and/or the air, it is preferable not to bring the light reflective filler into contact. Further, resin that allows little gas such as the atmosphere to pass therethrough, such as epoxy resin, is commonly used as resin of the first insulating section 809a, to which titanium dioxide is to be added, resin of the second insulating section 809b, to which titanium dioxide is to be added, and the third insulating section 909c, to which titanium dioxide is to be added. It is thus especially preferable to provide a titanium dioxide-added resin layer 509c inside of the resin of the first insulating section 809a, the resin of the second insulating section 809b, and the resin of the third insulating section 909c.

Accordingly, it is preferable that the first insulating section 809a, the second insulating section 809b, and the third insulating section 909c each have a multilayer structure in which a light reflective filler-free resin layer containing no light reflective filler and a light reflective filler-added resin layer containing the light reflective filler are stacked in this order from a side via which light enters. RCC resin absorbs light. Thus, it is preferable to form the light reflective filler-free resin layer, which does not contain the light reflective filler, in the form of a layer as thin as possible and then to form the light reflective filler-added resin layer, which contains the light reflective filler, in a lower layer on the light reflective filler-free resin layer.

Processes of forming the first insulating section 809a, the second insulating section 809b, and the third insulating section 909c are same as the process of forming the insulating section 509 of First Embodiment. Thus, description thereof is omitted here.

Use of titanium dioxide as the light reflective filler causes a conductive layer to oxidize by photocatalytic reaction in the presence of oxygen. Therefore, it is preferable in this case to form the light reflective filler as far as possible from the conductive layer. Further, to keep the light reflective filler away from the atmosphere containing oxygen, it is preferable that a front surface of the mount surface do not contain the light reflective filler.

Accordingly, it is preferable that the first insulating section 809a, the second insulating section 809b, and the third insulating section 909c each have a multilayer structure in which a light reflective filler-free resin layer containing no light reflective filler and a light reflective filler-added resin layer containing the light reflective filler are stacked in this order from a side via which light enters. Epoxy resin absorbs light. Thus, it is preferable to form the light reflective filler-free resin layer, which does not contain the light reflective filler, in the form of a layer as thin as possible and then to form the light reflective filler-added resin layer, which contains the light reflective filler, in a lower layer on the light reflective filler-free resin layer.

Processes of forming the first insulating section 809a, the second insulating section 809b, and the third insulating section 909c are same as the process of forming the insulating section 509 of First Embodiment. Thus, description thereof is omitted here.

It is also possible with the use of titanium dioxide as the light reflective filler to improve the intensity of light emitted from a light outgoing surface while preventing the problem of oxidization of the metallic reflecting plate 802, the light-transmitting sealant 510, the first insulating section 809a, the second insulating section 809b, and/or the third insulating section 909c in the presence of oxygen due to photocatalytic reaction of the light reflective filler and the problem of peel-off of the light-transmitting sealant 510, compared with the case in which the light reflective filler is added all over the first insulating section 809a, the second insulating section 809b, and the third insulating section 909c.

In other words, it is possible to reduce the amount of light absorbed by the first and second insulating sections 809a and 809b and by the third insulating section 909c, and the amount of light passing through the substrate to be emitted to the outside via the rear surface. Thus, efficiency for light utilization and heat releasing property improve.

The resin containing the light reflective filler is used in the first insulating section 809a, in the second insulating section 809b, and in the third insulating section 909c so that the light reflective filler is allowed to reflect light that is emitted from the LED chip 701 and enters the first insulating section 809a, the second insulating section 809b, and the third insulating section 909c, and light that is emitted from a fluorescent material contained in the light-transmitting sealant 510, which seals the LED chip 701, and enters the first insulating section 809a, the second insulating section 809b, and the third insulating section 909c. This makes it possible to reduce light that is partially absorbed and becomes attenuated when entering the first insulating section 809a, the second insulating section 809b, and the third insulating section 909c and being reflected by a peripheral component, so that efficiency for light utilization and heat releasing property improve.

It is preferable that the RCC resin be formed by thermal processing in an atmosphere of inert gas. This makes it possible to prevent resin used in the first insulating section 809a, in the second insulating section 809b, and in the third insulating section 909c from deteriorating (changing to yellow), so that the foregoing effect is produced efficiently without absorption of light by the resin having deteriorated.

In the same manner as in the embodiments discussed above, the light emitting device 900 is arranged in such a manner that the metallic reflecting plate 802, which reflects light from the LED chips 701 and 901 to guide the light to the light outgoing surface 513 provided in the direction in which light is emitted, is provided in the direction in which the LED chips 701 and 901 emit light, and that the metallic reflecting plate 802 is provided so as to surround the LED chips 701 and 901 entirely. This allows the metallic reflecting plate 802 to reflect light emitted from the LED chips 701 and 901 to its surrounding area to efficiently guide the light to the light outgoing surface 513. It thus becomes possible to reduce leakage of light from a side surface of the element so that the intensity of light emitted from the light outgoing surface 513 improves.

As shown in FIG. 21, the light emitting device 900 of the present embodiment is arranged in such a manner that the metallic reflecting plate 802 and the mount-surface metallic reflecting film 920 are combined together.

This makes it possible to form the mount-surface metallic reflecting film 920 over a wide area of the mount surface. Increasing this metal-formed area in the whole element makes it possible to realize a light emitting device having excellent heat releasing property. It also becomes possible to convey heat generated at the time of emission of light from the LED chips 701 and 901 to a front surface of the multilayer substrate 606, with which the mount-surface metallic reflecting film 920 is combined, and release the heat to a rear surface effectively. The foregoing makes it possible to reduce deterioration due to heat and therefore to realize a light emitting device with long-term reliability.

Further, as described above, the metallic reflecting plate 802 of the present embodiment is electrically isolated from all of the first island electrode 807, the second island electrode 808, and the third island electrode 908. Thus, as shown in FIG. 18, the metallic reflecting plate 802 does not come to have electric potential at the time of mounting the light emitting device 900 on a housing 400, which is made of metal such as aluminum, of an electronic device such as a mobile phone. Therefore, it is possible to mount the light emitting device 900 with the metallic reflecting plate 802 being in contact with the housing 400, without using intervening resin or the like having low heat releasing property. This allows heat generated in the metallic reflecting plate 802 to escape to the outside of the light emitting device 900 efficiently.

In the same manner as the light emitting devices 700 and 800 of Third and Fourth Embodiments, the light emitting device 900 according to the present embodiment is arranged in such a manner that a heat radiating sheet 740 for allowing heat generated in the metallic reflecting plate 802 to escape to the outside is formed on at least a part of an outer surface of the metallic reflecting plate 802 and on an outer surface of the element, including a bottom surface of the multilayer substrate 606.

The foregoing allows the heat generated in the metallic reflecting plate 802 to escape to the outside via the heat radiating sheet 740 more efficiently. Therefore, the light emitting device 900 with long-term reliability is realized.

It is preferable to use a conductive material with excellent heat releasing property as the heat radiating sheet 740. As described above, the metallic reflecting plate 802 according to the present embodiment is isolated from the other components, so that it does not come to have electric potential. Therefore, the heat generated in the metallic reflecting plate 802 is allowed to efficiently escape to the outside via the heat radiating sheet, which is made of the conductive material having excellent heat releasing property, without causing a problem of short-circuit or the like. Use of a graphite-series material, which is especially excellent in heat releasing property, as the conductive material is preferred.

Further, this conductive heat radiating sheet is grounded so as to be isolated from the rear electrode on the housing. Thus, electric potential of the mount-surface metallic reflecting film having a metallic reflecting plate and an LED chip 701 that is electrically and thermally connected to the metallic reflecting plate does not float. This prevents an unnecessary electrical surge to flow into the LED chip 701 to damage the light emitting device or to cause the light emitting device to operate improperly.

Although the foregoing discusses the structure having two LED chips, the present embodiment is not limited to this structure. The present embodiment is also applicable to a structure having four LED chips, such as the light emitting device 900b shown in FIG. 35.

In a case in which two LED chips are connected serially in the structure shown in FIG. 21, and in a case in which sets of two LED chips connected parallel are connected serially in the structure shown in FIG. 35, two island electrodes are electrically connected to different rear electrodes to have different electric potentials in such a manner that one of the two island electrodes becomes an anode and the other one of the two island electrodes becomes a cathode as shown in FIG. 36. In a case in which two LED chips are connected parallel in the structure shown in FIG. 21, and in a case in which four LED chips are connected parallel in the structure shown in FIG. 35, the two island electrodes have the same electric potential as shown in FIG. 37. In this case, those two island electrodes include conductive sections in the layers of the multilayer substrate so that each of the two island electrodes is electrically connected to one of the rear electrodes (not illustrated).

Plural LED chips are provided and mounted properly in a single light emitting device so that it becomes possible to improve the intensity of emitted light without an increase of the size of the element. The maximum number of LED chips to be provided is not limited to four, and it is possible in a structure with a larger element substrate to provide more LED chips.

The foregoing discusses that the mount-surface metallic reflecting film 820 having the LED chip is grounded via the conductive heat radiating sheet at the time of mounting on the housing 400, which is made of metal such as aluminum, of an electronic device, such as a mobile phone, so that it does not float, whereby improper operation and damage of the light emitting device due to an electrical surge or the like are prevented. Instead of this way, it is also possible to employ the following way. For example, the multilayer substrate of FIG. 32 is arranged as shown in FIG. 21 so that conductive sections of respective layers of the multilayer substrate are provided in such a manner that the mount-surface metallic reflecting film having the LED chip 501 is electrically and thermally connected to the third rear electrode, which is a different electrode isolated from the first and second rear electrodes connected to an anode and a cathode of an external power, and the third rear electrode is connected to an external grounded terminal isolated from both the anode and the cathode. This makes it possible to further improve the heat releasing property of the LED chip 501 with the third rear electrode.

The same is applicable to arrangements of FIGS. 20 and 32-35 as discussed in the Fourth Embodiment.

Accordingly, the respective light emitting devices of the present invention discussed in the embodiments above are remedied in light leakage to have high light emission efficiency and have excellent heat releasing property, so that they are suitably applicable to a backlight unit having a waveguide provided near a light outgoing surface.

With a display element of the present invention, a backlight unit that is high in efficiency for light utilization and excellent in long-term reliability is realized.

### Sixth Embodiment

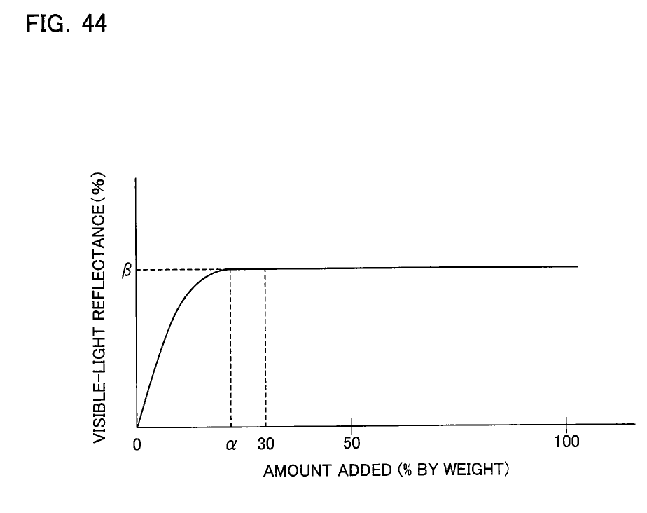

The following describes another embodiment of the present invention, with reference to FIGS. 43 and 44. For the convenience of explanation, components having the same functions as those of the components shown in the figures of the foregoing embodiments are given the same reference numbers, and description thereof is omitted.

In the respective embodiments discussed above, the insulating section has the multilayer structure in which the light reflective filler-free resin layer containing no light reflective filler and the light reflective filler-added resin layer containing the light reflective filler are stacked. On the contrary, in the present embodiment, the reflective filler is added to all over the insulating section.

FIG. 43 is a sectional view of a light emitting device 1000 according to the present embodiment. The light emitting device 1000 includes an insulating section 1009 in place of the insulating section 509 of the light emitting device 500 shown in FIG. 2. The light reflective filler is added to all over the insulating section 1009. This is a difference from the insulating section 509. This makes it possible to keep production costs low, compared with the case in which the insulating section has the multilayer structure.

Aluminum oxide, silicon oxide, titanium dioxide and the like, all of which are high in optical reflectance, are usable as the light reflective filler. As discussed above, the use of titanium dioxide as the light reflective filler has a risk of oxidization of a metallic reflecting plate 502, a light-transmitting sealant 510, and/or the insulating section 1009 due to photocatalytic reaction in the presence of oxygen during light emission operation (this oxygen originates from the atmosphere and/or moisture that have passed through the sealing resin, have been absorbed by peripheral components, and have stayed therein). On the other hand, when other reflective filler, such as aluminum oxide and silicon oxide, is used, the photocatalysis above does not occur. However, aluminum oxide and silicon oxide have hygroscopicity. Thus, there is a risk that the atmosphere and/or moisture absorbed in the process of sealing with the light-transmitting sealant 510 is vaporized by heat during light emission operation to cause the light-transmitting sealant 510 to peel off.

Accordingly, the amount of light reflective filler added is restricted in the present embodiment. The following discusses the amount of light reflective filler added.

FIG. 44 is a graph showing the relationship between a visible-light optical reflectance of the insulating section 1009 and the amount of light reflective filler added. The reflectance of the insulating section 1009 becomes saturated at β% when the amount of light reflective filler added is α% by weight. If the amount of light reflective filler added is small, the reflectance decreases because the light passes through the insulating section 1009 and/or is absorbed by the insulating section 1009. If the amount of light reflective filler added is α% by weight or below, it is difficult to specify the reflectance of the insulating section 1009 because of variation in the amount to be added. Therefore, the amount of light reflective filler added is set above α% by weight.

If the amount of light reflective filler added is too large, there arise risks of oxidization of the metallic reflecting plate 502 and the like or peel-off of the light-transmitting sealant 510. Therefore, the amount of light reflective filler added is set above α% by weight but close to α% by weight.

Further, a thermal cycling test was performed on the light emitting device 1000 under a highly-humid environment to measure an impact of thermal expansion/contraction of the luminescent element 1000 and resistance to temperature change. In the thermal cycling test, a cycle in which ambient temperature was changed from a low temperature (−40° C.) to a high temperature (120° C.) over a period of 30 minutes was repeated for 1000 times.

As a result of the test, it was round that cracks are likely to occur when too much light reflective filler was added to the insulating section 1009. Concretely, no crack was observed when the amount of light reflective filler added was 30% (resin: 70%), but cracks were observed when the amount of light reflective filler added was 36% (resin: 64%). In the test, titanium dioxide was used as the light reflective filler, silica was added to the insulating section 1009 to adjust the coefficient of thermal expansion, and the silica was partially replaced with titanium dioxide.

In the present embodiment, the upper limit of the amount of light reflective filler added is set to 30% by weight or below, i.e. α<A≦30, where A is the amount of light reflective filler added.

Accordingly, in the case in which the light reflective filler is added to all over the insulating section 1009, restricting the amount of light reflective filler added makes it possible to improve the efficiency for light utilization while the problems of oxidization of the metallic reflecting plate 502 and the like and of peel-off of the light-transmitting sealant 510 and cracks in the light emitting device 1000 are avoided.

### OVERVIEW OF EMBODIMENTS

The present invention is not limited to the description of the embodiments above, but may be altered by a skilled person within the scope of the claims. An embodiment based on a proper combination of technical means disclosed in different embodiments is encompassed in the technical scope of the present invention.

A light emitting device of the embodiments includes an insulating section having a light reflective filler-added area to which a light reflective filler is added and a light reflective filler-free area to which the light reflective filler is not added. This makes it possible to reduce light that is partially absorbed and becomes attenuated when entering the insulating section and being reflected by a peripheral component, so that efficiency for light utilization and heat releasing property improve.

In this structure, it is preferable that the insulating section contain the light reflective filler only in an exposed part of a mount surface.

In this structure, it is preferable to use aluminum oxide, silicon oxide, or titanium dioxide as the light reflective filler. Titanium dioxide is especially preferable because it has high optical reflectance and is inexpensive.

As discussed in Publication 2, titanium dioxide is added to resin in a reflecting component to change the color of the resin to white so that reflectance increases.

However, the use of titanium dioxide as the light reflective filler has a risk of oxidization of a metallic reflecting plate, a light-transmitting sealant, and/or an insulating section due to photocatalytic reaction in the presence of oxygen during light emission operation (this oxygen originates from the atmosphere and/or moisture that have passed through the sealing resin, have been absorbed by peripheral components, and have stayed therein). On the other hand, when other reflective filler, such as aluminum oxide and silicon oxide, is used, the photocatalysis above does not occur. However, aluminum oxide and silicon oxide have hygroscopicity. Thus, there is a risk that the atmosphere and/or moisture absorbed in the process of sealing with a light-transmitting sealant is vaporized by heat during light emission operation to cause the light-transmitting sealant to peel off. It is preferable that the light-transmitting sealant for sealing the LED chip be excellent in light resistance and in hermetic property. However, a resin having a greater light resistance generally allows much gas, such as the atmosphere, to pass through, so that the atmosphere and/or moisture may come to a mount surface.

Accordingly, in a case in which the light reflective filler is to be added to a front layer close to the mount surface, it is especially preferable to reduce the amount of light reflective filler added. This makes it possible to improve the optical reflectance, and at the same time, reduce the amount of active oxygen for oxidization.

In this structure, it is preferable that the insulating section have a multilayer structure in which a light reflective filler-free resin layer that does not contain the light reflective filler and a light reflective filler-added resin layer that contains the light reflective filler are stacked in this order from a side via which light enters.

The light reflective filler made of titanium dioxide causes oxidization of, for example, a conductive layer formed on a lower part of an insulating section due to photocatalytic reaction in the presence of oxygen.

Therefore, it is preferable not to add the light reflective filler to a front surface of the mount surface to keep it away from the atmosphere containing oxygen.

With this structure, the insulating section has the multilayer structure in which the light reflective filler-free resin layer that does not contain the light reflective filler and the light reflective filler-added resin layer that contains the light reflective filler are stacked in this order from the side via which light enters. This makes it possible to improve efficiency for light utilization while preventing the problem of oxidization of the metallic reflecting plate, the light-transmitting sealant, and/or the insulating section due to photocatalytic reaction of the light reflective filler in the presence of oxygen and the problem of peel-off of the light-transmitting sealant.

To avoid contact with moisture and the air, it is preferable in the foregoing structure not to contain the light reflective filler near a boundary surface of a layer bonding the mount surface or the insulating section to other components. Because the boundary surface separating from the bonding layer or from the other components is likely to hold moisture and/or the air, it is preferable not to bring the light reflective filler into contact.

Further, resin that allows little gas such as the atmosphere to pass therethrough, such as epoxy resin, is commonly used in the insulating section to which titanium dioxide is added. Thus, it is especially preferable to provide the reflective filler-added resin layer in the resin of the insulating section.

In this structure, it is preferable that the light reflective filler reflect light having a wavelength in the range of 400 nm to 850 nm, that is to say visible light rays.

In this structure, it is preferable that an optical reflectance of resin containing the light reflective filler be 50% or above when the wavelength is in the range.

The optical reflectance of RCC resin (resin coated copper) containing titanium dioxide is not 100% but approximately 50% to 70%, so that the remaining part transmits light. Therefore, if the RCC resin containing titanium dioxide is used, light is scattered inside of the RCC resin so that the light leaks to the layer bonding it to other components. If the light reflective filler-added resin layer is present all over the RCC resin, oxygen and the leaked light that are absorbed through or by other components cause electrodes or the like provided in the RCC resin, the other components, and the bonding layer to be oxidized owing to photocatalytic reaction, for example. It is thus preferable to form the light reflective filler-added resin layer (area) in the shape of a thin layer.

To solve the above problems, a method of producing a light emitting device of the embodiments is adapted so that the method includes forming the insulating section, including (a) forming the light reflective filler-free resin layer and (b) forming the light reflective filler-added resin layer. The light reflective filler-free resin layer and the light reflective filler-added resin layer is formed in a desired order so as to produce a multilayer structure on a metal foil.

It is also possible to bond the multilayer structure to a metal plate having the first metal section and the second metal section by thermally pressing a rear surface (surface opposite to a surface via which light is emitted).

In this structure, it is preferable that the multilayer structure constituted of the light reflective filler-free resin layer and the light reflective filler-added resin layer be formed by carrying out thermal processing in an atmosphere of inert gas.

With this structure, it becomes possible to prevent resin used in the respective insulating sections from deteriorating (changing to yellow), so that the foregoing effect is produced efficiently without absorption of light by the resin having deteriorated.

In this structure, it is preferable that the light-transmitting sealant, with which the LED chip is sealed in such a manner that the area surrounded by the substrate and the metallic reflecting plate is filled with the light-transmitting sealant, be formed by carrying out thermal hardening in an atmosphere of inert gas.

The thinnest thickness of a resin layer produced by a current production line for the RCC resin is 3 μm. Thus, it is preferable that the titanium dioxide-added resin layer be provided at least 3 μm away from the bonding layer, in view of limit of controllability of the thickness of an applied resin layer.

Further, resin absorbs light. Thus, it is preferable to form the light reflective filler-free resin layer in the shape of a layer as thin as possible and then to form the light reflective filler-added resin layer on a lower part of the light reflective filler-free resin layer.

Use of RCC resin as the resin is preferable. The RCC resin is in the form of paste similar to liquid that is slightly solidified. The light reflective filler such as titanium dioxide is mixed into RCC resin that is in the state of liquid. It is therefore difficult in a single-layer RCC resin to control the position of the light reflective filler-added resin layer containing the light reflective filler. Thus, the light reflective filler-added resin layer is solidified first, and then RCC resin that does not contain the light reflective filler is applied again onto the light reflective filler-added resin layer to form the light reflective filler-free resin layer, whereby the reflective filler is not contained in the front surface of the mount surface.

Accordingly, the use of the resin containing the light reflective filler in the insulating section allows the light reflective filler to reflect light that is emitted from the LED chip and enters the insulating section. This makes it possible to reduce light that is partially absorbed and becomes attenuated when entering the insulating section and being reflected by a peripheral component, so that efficiency for light utilization and heat releasing property improve.

A light emitting device according to the embodiments is adapted so that the light emitting device includes: an LED chip mounted on a substrate; and an insulating section formed on a front surface of the substrate and made of light-transmitting resin. The insulating section has a light reflective filler added to all over the insulating section.

A light emitting device according to the embodiments is adapted so that the light emitting device includes: a first metal section formed on a mount surface of a substrate and serving as a mount-surface metallic reflecting film; at least one second metal section that is formed on the mount surface and is electrically isolated from the first metal section by an insulating section; an LED chip mounted on the first metal section and having a first electrode that is electrically connected to the first metal section and a second electrode that is electrically connected to the second metal section; a metallic reflecting plate that is combined with the first metal section so as to surround the mount surface and reflects light emitted from the LED chip to guide the light to a light outgoing surface provided in a direction in which the light is emitted; and a light-transmitting sealant that fills an area surrounded by the substrate and the metallic reflecting plate and is formed in such a manner that the LED chip is sealed with the light-transmitting sealant. The insulating section is made of resin that contains a light reflective filler and being formed so as to surround the second metal section in an area surrounded by the metallic reflecting plate.

It is preferable in the above structure that the amount of light reflective filler added be more than and close to an amount at which the visible-light reflectance of the insulating section is saturated.

It is preferable in the above structure that the amount of light reflective filler added be less than an amount at which the insulating section cracks in a thermal test in which the light emitting device is exposed to high temperature and low temperature repeatedly.

It is preferable in the above structure that the amount of light reflective filler added be less than 30% by weight.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A light emitting device, comprising:
an LED chip mounted on a substrate; and
an insulating section formed on a front surface of the substrate and made of light-transmitting resin,
the insulating section including a light reflective filler-added area to which a light reflective filler is added and a light reflective filler-free area to which no light reflective filler is added.

2. A light emitting device, comprising:
a first metal section formed on a mount surface of a substrate and serving as a mount-surface metallic reflecting film;
at least one second metal section that is formed on the mount surface and is electrically isolated from the first metal section by an insulating section;
an LED chip mounted on the first metal section and having a first electrode that is electrically connected to the first metal section and a second electrode that is electrically connected to the second metal section;
a metallic reflecting plate that is combined with the first metal section so as to surround the mount surface and reflects light emitted from the LED chip to guide the light to a light outgoing surface provided in a direction in which the light is emitted; and
a light-transmitting sealant that fills an area surrounded by the substrate and the metallic reflecting plate and is formed in such a manner that the LED chip is sealed with the light-transmitting sealant,
the insulating section being made of resin that contains a light reflective filler and being formed so as to surround the second metal section in an area surrounded by the metallic reflecting plate.

3. The light emitting device of claim 1, wherein the insulating section contains the light reflective filler only in an exposed part of the mount surface.

4. The light emitting device of claim 1, wherein the insulating section has a multilayer structure in which a light reflective filler-free resin layer that does not contain the light reflective filler and a light reflective filler-added resin layer that contains the light reflective filler are stacked in this order from a side via which light is emitted.

5. The light emitting device of claim 1, wherein the light reflective filler is not contained near a boundary surface that is to be bonded to another component via a bonding layer.

6. The light emitting device of claim 1, wherein the light reflective filler reflects light having a wavelength in a range of 400 nm to 850 nm.

7. The light emitting device of claim 6, wherein an optical reflectance of resin containing the light reflective filler is 50% or above with respect to the wavelength in the range.

8. The light emitting device of claim 1, wherein the light reflective filler is made of aluminum oxide, silicon oxide, or titanium dioxide.

9. A method of producing a light emitting device including: an LED chip mounted on a substrate; and an insulating section formed on a front surface of the substrate and made of light-transmitting resin, the insulating section including a light reflective filler-added area to which a light reflective filler is added and a light reflective filler-free area to which no light reflective filler is added,
the method comprising:
forming the insulating section, including (a) forming the light reflective filler-free resin layer and (b) forming the light reflective filler-added resin layer,
the light reflective filler-free resin layer and the light reflective filler-added resin layer being formed in a desired order so as to produce a multilayer structure on a metal foil.

10. A method of producing a light emitting device including: a first metal section formed on a mount surface of a substrate and serving as a mount-surface metallic reflecting film; at least one second metal section that is formed on the mount surface and is electrically isolated from the first metal section by an insulating section; an LED chip mounted on the first metal section and having a first electrode that is electrically connected to the first metal section and a second electrode that is electrically connected to the second metal section; a metallic reflecting plate that is combined with the first metal section so as to surround the mount surface and reflects light emitted from the LED chip to guide the light to a light outgoing surface provided in a direction in which the light is emitted; and a light-transmitting sealant that fills an area surrounded by the substrate and the metallic reflecting plate and is formed in such a manner that the LED chip is sealed with the light-transmitting sealant, the insulating section being made of resin that contains a light reflective filler and being formed so as to surround the second metal section in an area surrounded by the metallic reflecting plate,
the method comprising forming the insulating section, including (a) forming the light reflective filler-free resin layer and (b) forming the light reflective filler-added resin layer, and
the light reflective filler-free resin layer and the light reflective filler-added resin layer being formed in a desired order so as to produce a multilayer structure on a metal foil.

11. The method of claim 9, wherein the multilayer structure including the light reflective filler-free resin layer and the light reflective filler-added resin layer is formed by thermal processing performed in an atmosphere of inert gas.

12. The method of claim 9, wherein a light-transmitting sealant with which an area surrounded by the substrate and the metallic reflecting plate is filled such that the LED chip is sealed with the light-transmitting sealant is formed by thermal hardening performed in an atmosphere of inert gas.

13. A light emitting device, comprising:
an LED chip mounted on a substrate; and
an insulating section formed on a front surface of the substrate and made of light-transmitting resin,
the insulating section having a light reflective filler added to all over the insulating section.

14. The light emitting device of claim 2, wherein the light reflective filler is added to all over the insulating section.

15. The light emitting device of claim 13, wherein the amount of light reflective filler added is more than and close to an amount at which the visible-light reflectance of the insulating section is saturated.

16. The light emitting device of claim 15, wherein the amount of light reflective filler added is less than an amount at which the insulating section cracks in a thermal test in which the light emitting device is exposed to high temperature and low temperature repeatedly.
